(19) United States
(12) Patent Application Publication
(10) Pub. No.: US 2026/0311729 A1
(43) Pub. Date: Oct. 8, 2026

(54) MEMORY DEVICE AND METHOD FOR MANUFACTURING THE SAME

(71) Applicant: MACRONIX INTERNATIONAL CO., LTD., Hsinchu (TW)

(72) Inventors: Kuan-Yuan SHEN, Zhubei City (TW); Teng-Hao YEH, Zhubei City (TW); Guan-Ru LEE, Hsinchu City (TW)

(21) Appl. No.: 19/098,082

(22) Filed: Apr. 2, 2025

(51) Int. Cl. G11C 5/06; H10B 43/27

(52) U.S. Cl. CPC G11C 5/063; H10B 43/27

(57) ABSTRACT

A memory device and a method for manufacturing the same are provided. The memory device includes a substrate including an array region and a peripheral region, a first stacked structure and a second stacked structure in the array region, at least one transistor in the second stacked structure, and a metal routing layer above the first and the second stacked structures. The first stacked structure includes a first conductive layer, a second conductive layer and an insulating layer between the first and the second conductive layers. The first conductive layer, the insulating layer and the second conductive layer are stacked along a first direction. The at least one transistor includes a conductive film, a dielectric film and a semiconductor film stacked along the first direction. The metal routing layer is electrically connected to the at least one transistor, the first conductive layer and the second conductive layer.

### BACKGROUND

### Technical Field

The disclosure relates to a semiconductor structure and a method for manufacturing the same, and more particularly to a memory device and a method for manufacturing the same.

### Description of the Related Art

Generally, a memory device includes memory cells (which can form a memory array) in an array region and a peripheral circuit in a peripheral region. The peripheral circuit can be electrically connected to the memory array to operate the memory cells. The sequence of manufacturing steps for a memory device can limit the design of the memory device. For example, process temperature may limit material options for elements in the memory device, resulting in poor performance of the memory device.

### SUMMARY

The present disclosure provides a memory device and a method for manufacturing the same, which can better integrate the peripheral region and the array region without limiting the design options of the peripheral region and the array region due to the manufacturing process, thereby improving the performance of the memory device.

According to embodiments of the present disclosure, a memory device is provided. The memory device includes a substrate including an array region and a peripheral region, a first stacked structure in the array region, a second stacked structure in the peripheral region, at least one transistor in the second stacked structure, and a metal routing layer above the first stacked structure and the second stacked structure. The first stacked structure includes a first conductive layer, a second conductive layer and an insulating layer between the first conductive layer and the second conductive layer. The first conductive layer, the insulating layer and the second conductive layer are stacked along a first direction. The at least one transistor includes a conductive film, a dielectric film and a semiconductor film stacked along the first direction. The metal routing layer electrically connected to the at least one transistor, the first conductive layer and the second conductive layer.

According to embodiments of the present disclosure, a method for manufacturing a memory device is provided. The method includes: providing a substrate including an array region and a peripheral region; forming a layer stack in the array region, wherein the layer stack includes a semiconductor material layer, a dielectric layer and an insulating layer between the semiconductor material layer and the dielectric layer; forming a channel pillar penetrating the layer stack; forming an extension portion adjoining the layer stack, wherein the extension portion includes semiconductor layers extending and stacked along a first direction and a second direction perpendicular to the first direction; forming at least one transistor in the peripheral region, wherein the at least one transistor includes a conductive film, a dielectric film and a semiconductor film stacked on top of one another.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic cross-sectional view of a memory device according to an embodiment of the present disclosure.

FIG. 2A illustrates a circuit diagram of the memory device of FIG. 1.

FIG. 2B shows a threshold voltage distribution diagram of the memory device of FIG. 1.

FIG. 3 illustrates a schematic cross-sectional view of a memory device according to another embodiment of the present disclosure.

FIG. 4 to FIG. 23 illustrate schematic cross-sectional views of structures at various stages of a method for manufacturing a memory device according to some embodiments of the present disclosure.

FIG. 24 to FIG. 37 illustrate schematic cross-sectional views of structures at various stages of a method for manufacturing a memory device according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “adjoin” refers to “adjacent to and contact”. As used in the specification and the appended claims, term “deposition” includes, but is not limited to, chemical vapor deposition (CVD), physical vapor deposition (PVD), atomic layer deposition (ALD) and epitaxial growth. Depending on the type of material to be formed, a person of ordinary skill in the art can select an appropriate technology for forming the material. As used in the specification and the appended claims, terms “etching” and “etching back” include, but are not limited to, dry etching and wet etching. As used in the specification and the appended claims, term “polishing process” includes, but is not limited to, a chemical-mechanical planarization (CMP) and an ion milling process. The terms “etching”, “etching back” and “polishing process” used in the specification and the appended claims may replace with each other, and a person of ordinary skill in the art can select an appropriate removal technology depending on the structure and material.

Embodiments according to the present disclosure can be applied to many different types of three-dimensional memory devices. For example, embodiments according to the present disclosure can be applied to, but not limited to, NAND type memory devices, NOR type memory devices or any type of memory devices. Embodiments according to the present disclosure can be applied to memory devices with CMOS near array (CNA) architecture, that is, the array region of the memory device (the memory array is in the array region) and the peripheral region (the peripheral circuit is in the peripheral region) are arranged side by side in the same wafer.

Embodiments according to the present disclosure will be illustrated below by taking an NOR type memory device as an example, but the present disclosure is not limited to a specific type of device.

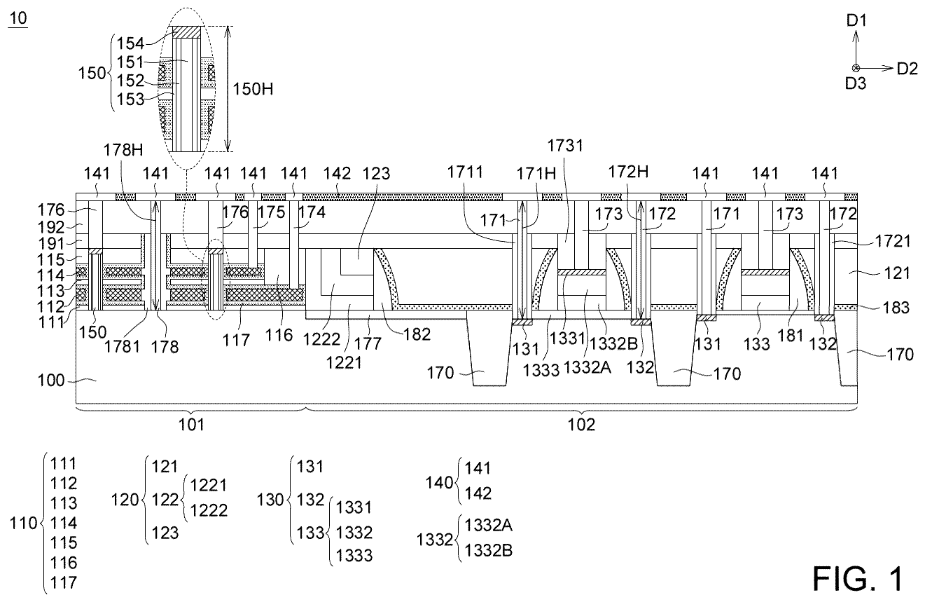

Referring to FIG. 1, FIG. 1 illustrates a schematic cross-sectional view of a memory device 10 according to an embodiment of the present disclosure. The memory device 10 includes a substrate 100, at least one stacked structure 110, at least one stacked structure 120, at least one transistor 130, and at least one metal routing layer 140 above the stacked structure 110 and the stacked structure 120. The substrate 100 includes an array region 101 and a peripheral region 102. The peripheral region 102 can be arranged near the array region 101. The peripheral region 102 can adjoin the array region 101. The array region 101 and the peripheral region 102 can be arranged along the second direction D2 and/or the third direction D3. The stacked structure 110 is in the array region 101. The stacked structure 110 is disposed on the substrate 100 along the first direction D1. The stacked structure 110 can include a conductive layer 112, a conductive layer 114 and an insulating layer 113 between the conductive layer 112 and the conductive layer 114. The conductive layer 112, the insulating layer 113 and the conductive layer 114 can be stacked along the first direction D1. The stacked structure 120 is in the peripheral region 102. The stacked structure 120 is disposed on the substrate 100 along the first direction D1. The stacked structure 120 can be disposed on a side of the stacked structure 110 in the second direction D2 and/or the third direction D3. The stacked structure 120 may adjoin the stacked structure 110. The transistor 130 is in the stacked structure 120. The transistor 130 includes a conductive film 1331, a dielectric film 1333 and a semiconductor film 1332 stacked along the first direction D1. The metal routing layer 140 can be electrically connected to the transistor 130, the conductive layer 112 and the conductive layer 114. The first direction D1, the second direction D2 and the third direction D3 can be perpendicular to each other. For example, the first direction D1 can be the normal direction of a surface of the substrate 100 facing the stacked structures 110 and 120, and the second direction D2 and the third direction D3 can be parallel to the surface of the substrate 100. The transistor 130 can be a portion of the peripheral circuit of the memory device 10. The peripheral circuit of the memory device 10 may include other active and/or passive devices, such as transistors, diodes, capacitors and resistors.

The stacked structure 110 may further include an insulating layer 111, an insulating layer 115, an insulating layer 116 and a barrier layer 117. The insulating layer 111, the conductive layer 112, the insulating layer 113, the conductive layer 114 and the insulating layer 115 may be stacked on the substrate 100 along the first direction D1. The insulating layer 111 may be disposed between the conductive layer 112 and the substrate 100. The conductive layer 112 is closer to the substrate 100 than the conductive layer 114. The barrier layer 117 may be disposed on or cover an upper surface of the conductive layer 112, a lower surface of the conductive layer 112, a sidewall of the conductive layer 112, an upper surface of the conductive layer 114, a lower surface of the conductive layer 114, and a sidewall of the conductive layer 114. The lower surface of the conductive layer 112 and the lower surface of the conductive layer 114 face the substrate 100. The barrier layer 117 may be between the insulating layer 111 and the conductive layer 112. The barrier layer 117 may be between the conductive layer 112 and the insulating layer 113. The barrier layer 117 may be between the insulating layer 113 and the conductive layer 114. The barrier layer 117 may be between the conductive layer 114 and the insulating layer 115. The barrier layer 117 may be between the insulating layer 116 and the conductive layer 112. The barrier layer 117 may be between the insulating layer 116 and the conductive layer 114. The insulating layer 116 may be disposed above the conductive layer 112 in the first direction D1. The insulating layer 116 may be disposed on a side of the conductive layer 114 in the second direction D2 and/or the third direction D3. The insulating layer 116 may adjoin the insulating layer 113 and the insulating layer 115.

The stacked structure 120 can include an insulating film 121, an extension portion 122 and an insulating film 123. The extension portion 122 may adjoin an end of the conductive layer 112. The extension portion 122 can include semiconductor layers extending and stacked along the first direction D1 and the second direction D2, such as a semiconductor layer 1221 and a semiconductor layer 1222. The number of the semiconductor layers included in the extension portion 122 is not limited to the number shown in FIG. 1. The extension portion 122 may include two semiconductor layers or more than two semiconductor layers. On the plane formed by the first direction D1 and the second direction D2, the semiconductor layer 1221 and the semiconductor layer 1222 may have L-shaped sections. The semiconductor layer 1221 and the semiconductor layer 1222 may extend on the plane formed by the second direction D2 and the third direction D3, and extend on the plane formed by the first direction D1 and the third direction D3. The semiconductor layer 1222 may be disposed on the semiconductor layer 1221. The insulating film 123 may be disposed on the semiconductor layer 1222. The insulating film 123 may adjoin an upper surface of the semiconductor layer 1222, and a sidewall of the semiconductor layer 1222 facing away from the stacked structure 110. The semiconductor layer 1221 may adjoin a sidewall of the insulating layer 116, a sidewall of the barrier layer 117 and a sidewall of the insulating layer 111. The extension portion 122 and the insulating film 123 may be disposed between the insulating film 121 and the stacked structure 110.

The transistor 130 includes a source 131, a drain 132 and a gate 133. The gate 133 is disposed between the source 131 and the drain 132. The source 131 and the drain 132 are in the substrate 100. The gate 133 is on the substrate 100. The gate 133 can be formed by the conductive film 1331, the dielectric film 1333 and the semiconductor film 1332. The semiconductor film 1332 may be disposed between the conductive film 1331 and the dielectric film 1333. The dielectric film 1333, the semiconductor film 1332 and the conductive film 1331 may be sequentially stacked along the first direction D1. In the present embodiment, the semiconductor film 1332 has a multi-layer structure, and the semiconductor film 1332 includes a semiconductor material film 1332A and a semiconductor material film 1332B stacked along the first direction D1; however, the present disclosure is not limited thereto; the semiconductor film 1332 may include three or more than three semiconductor material films, or the semiconductor film 1332 may have a single-layer structure. In the present embodiment, the heights of the dielectric films 1333 of two transistors 130 shown in FIG. 1 are different, but the present disclosure is not limited thereto.

The memory device 10 may further include at least one channel pillar 150, a plurality of memory cells MS, a plurality of shallow trench isolations (STI) 170, at least one source contact structure 171, at least one drain contact structure 172, at least one gate contact structure 173, at least one conductive contact structure 174, at least one conductive contact structure 175, at least one channel contact structure 176, at least one dielectric film 177, at least one conductive pillar 178, at least one spacer 181, at least one spacer 182, a cover layer 183, at least one separation element 1711, at least one separation element 1721, at least one separation element 1731, at least one separation element 1781, an interlayer insulating layer 191 and an interlayer insulating layer 192. The interlayer insulating layer 191 and the interlayer insulating layer 192 may extend on the plane formed by the second direction D2 and the third direction D3 and across the array region 101 and the peripheral region 102. The interlayer insulating layer 191 and the interlayer insulating layer 192 can be disposed between the stacked structure 110 and the metal routing layer 140 and can be disposed between the stacked structure 120 and the metal routing layer 140. The interlayer insulating layer 191 and the interlayer insulating layer 192 may be sequentially stacked along the first direction D1.

The channel pillar 150 can extend along a direction opposite to the first direction D1 (such as a negative first direction D1) and penetrate the stacked structure 110. The channel pillar 150 can be disposed in the array region 101 and on the substrate 100. The channel pillar 150 can include an insulating pillar 151, a channel layer 152, a charge storage layer 153 and a pad 154. The channel layer 152 may have a tubular shape and surround the insulating pillar 151. The charge storage layer 153 may have a tubular shape and surround the channel layer 152 and the insulating pillar 151. An outer sidewall of the charge storage layer 153 may contact the insulating layer 111, the insulating layer 113, the insulating layer 115 and the barrier layer 117. The barrier layer 117 can separate the channel pillar 150 from the conductive layer 112 and the conductive layer 114. The pad 154 can be disposed on or contact the first end of the insulating pillar 151, the first end of the channel layer 152 and the first end of the charge storage layer 153. The second end of the insulating pillar 151 opposite to the first end of the insulating pillar 151, the second end of the channel layer 152 opposite to the first end of the channel layer 152, and the second end of the charge storage layer 153 opposite to the first end of the charge storage layer 153 may contact the substrate 100. The memory cells MS are between the conductive layer 114 and the channel pillar 150.

The shallow trench isolations 170 can be disposed in the substrate 100. The shallow trench isolations 170 are disposed in the peripheral region 102 and below the stacked structure 120. The shallow trench isolations 170 and the transistors 130 can be disposed alternately. The transistors 130 can be electrically isolated from each other by the shallow trench isolations 170.

The source contact structure 171 and the drain contact structure 172 can extend along the direction opposite to the first direction D1 (such as a negative first direction D1) to a surface of the substrate. The source contact structure 171 can extend along the direction opposite to the first direction D1 (such as a negative first direction D1) to a surface of the source 131 of the transistor 130. The drain contact structure 172 can extend along the direction opposite to the first direction D1 (such as a negative first direction D1) to a surface of the drain 132 of the transistor 130. The gate contact structure 173 can extend along the direction opposite to the first direction D1 (such as a negative first direction D1) to a surface of the gate 133 of the transistor 130. The source contact structure 171, the drain contact structure 172 and the gate contact structure 173 can be separately disposed on the substrate 100. The source contact structure 171, the drain contact structure 172 and the gate contact structure 173 may penetrate the stacked structure 120, the interlayer insulating layer 191 and the interlayer insulating layer 192. The source contact structure 171 can be electrically connected to the source 131 of the transistor 130. The drain contact structure 172 can be electrically connected to the drain 132 of the transistor 130. The gate contact structure 173 can be electrically connected to the gate 133 of the transistor 130. In the present disclosure, a height 171H of the source contact structure 171 from the substrate 100 and a height 172H of the drain contact structure 172 from the substrate 100 are greater than a height 150H of the channel pillar 150 from the substrate 100. The height 171H, the height 172H and the height 150H are in the first direction D1. The height 171H can also be understood as the distance between the upper surface of the source contact structure 171 and the upper surface of the source 131. The height 172H can also be understood as the distance between the upper surface of the drain contact structure 172 and the upper surface of the drain 132. The height 150H can also be understood as the distance between the upper surface of the pad 154 and the surface of the substrate 100.

The separation element 1711, the separation element 1721 and the separation element 1731 are on the substrate 100. The separation element 1711, the separation element 1721 and the separation element 1731 may penetrate the stacked structure 120 and the interlayer insulating layer 191. The separation element 1711 can be disposed on a sidewall of the source contact structure 171. The separation element 1711 may surround the source contact structure 171. The source contact structure 171 may extend beyond the separation element 1711. The separation element 1721 can be disposed on a sidewall of the drain contact structure 172. The separation element 1711 may surround the drain contact structure 172. The drain contact structure 172 may extend beyond the separation element 1721. The separation element 1731 can be disposed on a sidewall of the gate contact structure 173. The separation element 1731 may surround the gate contact structure 173. The gate contact structure 173 may extend beyond the separation element 1731. In the present embodiment, the upper surfaces the separation element 1711, the separation element 1721 and the separation element 1731 may be at the same height as the upper surface of the interlayer insulating layer 191.

The spacer 181, the spacer 182 and the cover layer 183 are disposed on the substrate 100. The spacer 181, the spacer 182 and the cover layer 183 are disposed in the peripheral region 102. The spacer 181, the spacer 182 and the cover layer 183 can be disposed in the stacked structure 120. The spacer 181 can be disposed on a sidewall of the gate 133 of the transistor 130. The spacers 181 can be disposed on opposite sidewalls of the gate 133 of the transistor 130. The spacer 181 can be disposed on sidewalls of the conductive film 1331 and the semiconductor film 1332 of the gate 133 of the transistor 130. The spacer 181 can be disposed above the dielectric film 1333 of the gate 133. The spacer 181 may be between the source 131 and the semiconductor film 1332. The spacer 181 may be between the drain 132 and the semiconductor film 1332. The spacer 181 may contact the dielectric film 1333, the semiconductor film 1332, the conductive film 1331 and the separation element 1731. An end of the spacer 181 can be higher than an upper surface of the conductive film 1331 in the first direction D1. The spacer 182 can be disposed on a sidewall of the extension portion 122 and a sidewall of the insulating film 123. The spacer 182 can be disposed at an end of the extension portion 122 away from the conductive layer 112. The spacer 182 may be disposed above the dielectric film 177. A height of the spacer 181 in the first direction D1 and a height of the spacer 182 in the first direction D1 can be substantially the same. The cover layer 183 may cover the spacers 181, the spacer 182 and the shallow trench isolations 170. The cover layer 183 may cover the dielectric film 177. The cover layer 183 may be between the insulating film 121 and the space 182. The cover 183 may be between the insulating film 121 and the dielectric film 177. The cover 183 may be between the insulating film 121 and the shallow trench isolation 170. The cover layer 183 may be between the insulating film 121 and the spacer 181.

The dielectric film 177 are disposed in the peripheral region 102 and below the stacked structure 120. The dielectric film 177 may extend from the boundary of the peripheral region 102 to the shallow trench isolation 170. In the present embodiment, a height of the dielectric film 177 in the first direction D1 and the height of the dielectric film 1333 of the transistor 130 adjacent to the dielectric film 177 are substantially the same, but the present disclosure is not limited thereto.

The conductive pillar 178 is disposed on the substrate 100. The conductive pillar 178 is disposed in the array region 101. The conductive pillar 178 may penetrate the stacked structure 110, the interlayer insulating layer 191 and the interlayer insulating layer 192. The conductive pillar 178 can extend along the direction opposite to the first direction D1 (such as a negative first direction D1) to a surface of the substrate. The conductive pillar 178 can be electrically connected to the substrate 100. The separation element 1781 is disposed on the substrate 100. The separation element 1781 may penetrate the stacked structure 110 and the interlayer insulating layer 191. The separation element 1781 can be disposed on a sidewall of the conductive pillar 178. The separation element 1781 may surround the conductive pillar 178. The conductive pillar 178 may extend beyond the separation element 1781.

The conductive contact structure 174 and the conductive contact structure 175 can be separately disposed on the substrate 100. The conductive contact structure 174 and the conductive contact structure 175 are disposed in the array region 101. The conductive contact structure 174 is above the conductive layer 112. The conductive contact structure 174 can land on or contact the conductive layer 112. The conductive contact structure 174 can penetrate the interlayer insulating layer 192, the interlayer insulating layer 191, the insulating layer 116 and a portion of the barrier layer 117 on the upper surface of the conductive layer 112, and can be electrically connected to the conductive layer 112. The conductive contact structure 175 is above the conductive layer 114. The conductive contact structure 175 can land on or contact the conductive layer 114. The conductive contact structure 175 can penetrate the interlayer insulating layer 192, the interlayer insulating layer 191, the insulating layer 115 and a portion of the barrier layer 117 on the upper surface of the conductive layer 114, and can be electrically connected to the conductive layer 114. The height 171H of the source contact structure 171 from the substrate 100 and the height 172H of the drain contact structure 172 from the substrate 100 can be greater than a height 178H of the conductive pillar 178 from the substrate 100. The height 178 is in the first direction D1. The height 178H can also be understood as the distance between the upper surface of the conductive pillar 178 and the surface of the substrate 100.

The channel contact structure 176 is disposed on the substrate 100. The channel contact structure 176 is disposed in the array region 101. The channel contact structure 176 is disposed above the channel pillar 150 and the stacked structure 110. The channel contact structure 176 may extend along the first direction D1 and penetrate the interlayer insulating layer 191 and the interlayer insulating layer 192. The channel contact structure 176 may be disposed between the channel pillar 150 and the metal routing layer 140.

The metal routing layer 140 can include an insulating material 142 and conductive lines 141. One of the conductive lines 141 may be electrically connected to the source 131 through the source contact structure 171. One of the conductive lines 141 may be electrically connected to the drain 132 through the drain contact structure 172. One of the conductive lines 141 may be electrically connected to the gate 133 through the gate contact structure 173. One of the conductive lines 141 may be electrically connected to the substrate 100 through the conductive pillar 178. The conductive contact structure 174 and the conductive contact structure 175 are electrically connected to the conductive lines 141 of the metal routing layer 140. One of the conductive lines 141 may be electrically connected to the conductive layer 112 through the conductive contact structure 174. One of the conductive lines 141 may be electrically connected to the conductive layer 114 through the conductive contact structure 175. One of the conductive lines 141 may be electrically connected to the channel pillar 150 through the channel contact structure 176.

The number of elements included in the memory device 10 is not limited to the number shown in FIG. 1, and the number of each element can be increased or reduced as required.

The transistor formed at the intersections of the conductive layer 112 and the channel pillar 150 can be used as a selection transistor, and the conductive layer 112 can be functioned as a selection gate line. The transistor formed at the intersection of the conductive layer 114 and the channel pillar 150 can be used as a data storage transistor, and the conductive layer 114 can be functioned as a word line. The conductive line 141 of the metal routing layer 140 electrically connected to the channel pillar 150 can be functioned as a bit line.

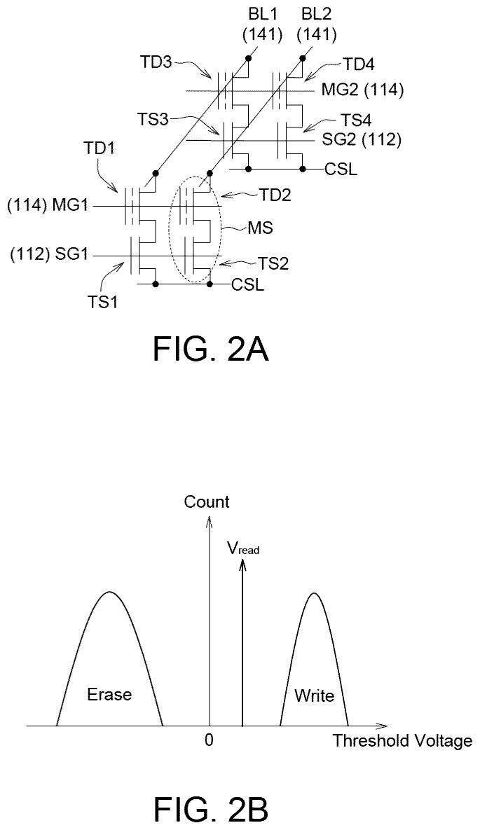

Referring to FIGS. 1 and 2A, FIG. 2A illustrates a circuit diagram of the memory device 10 of FIG. 1. FIG. 2A shows four data storage transistors TD1~TD4 and four selection transistors TS1~TS4. The data storage transistor TD1 is connected in series with the selection transistor TS1. The data storage transistor TD2 is connected in series with the selection transistor TS2. The data storage transistor TD3 is connected in series with the selection transistor TS3. The data storage transistor TD4 is connected in series with the selection transistor TS4. The data storage transistor TD1 and the selection transistor TS1 forms a memory cell MS and are electrically connected between a bit line BL1 and a common source line CSL. The data storage transistor TD2 and the selection transistor TS2 forms a memory cell MS and are electrically connected between a bit line BL2 and a common source line CSL. The data storage transistor TD3 and the selection transistor TS3 forms a memory cell MS and are electrically connected between a bit line BL1 and a common source line CSL. The data storage transistor TD4 and the selection transistor TS4 forms a memory cell MS and are electrically connected between a bit line BL2 and a common source line CSL. The data storage transistors TD1 and TD2 are electrically connected to a word line MG1. The selection transistors TS1 and TS2 are electrically connected to the selection gate line SG1. The data storage transistors TD3 and TD3 are electrically connected to a word line MG2. The selection transistors TS3 and TS4 are electrically connected to the selection gate line SG2. For example, the operation of the memory device 10 may include: applying a voltage to the bit line BL1 and the common source line CSL electrically connected to the data storage transistor TD1 and the selection transistor TS1, applying a voltage to the word line MG1 electrically connected to the data storage transistor TD1, and applying a voltage to the selection gate line SG1 electrically connected to the selection transistor TS1 to perform a read, write or erase operation.

Referring to FIG. 2B, FIG. 2B shows a threshold voltage distribution diagram of the memory device 10 of FIG. 1 in a write state and an erase state. In FIG. 2B, the horizontal axis represents the threshold voltage Vt, and the vertical axis represents the number of memory cells (count). The read voltage V_{read} in FIG. 2B can be applied to the word line during the read operation to identify the data stored in the memory cell. The read voltage V_{read} is usually set between the erase voltage and the write voltage. In a comparative example where the memory cell does not include a selection transistor, the erase voltage is set slightly higher than 0 V to prevent the data storage transistor from being in a normally ON state, the write voltage must be set to a higher value to ensure that the memory device has sufficient sensing window to perform a read operation, and thus a charge pump circuit must be used to boost the voltage. In the memory device according to the present disclosure, since the memory cell includes a data storage transistor and a selection transistor which can be used to turn on or off the data storage transistor, the threshold voltage distribution of the data storage transistor in the erase state can be set to a lower value (as compared with the comparative example), and the threshold voltage distribution of the data storage transistor in the write state can also be set to a lower value (compared to the comparative example); for example, the threshold voltage distribution of the data storage transistor in the erase state can be set to less than 0 V (as shown in FIG. 2B); even though such setting of the threshold voltage distribution may cause the data storage transistor to be in a normally ON state, current leakage can be avoided by turning off the selection transistor. Therefore, in the memory device according to the present disclosure, a lower read voltage (for example, the read voltage can be set to the supply voltage Vdd) and a lower write voltage can be achieved, the charge pump circuit for boosting the voltage can be omitted, the circuit design can be simplified, the setup time of the word line can be shortened, and the operation speed can be accelerated. The memory device according to the present disclosure is beneficial for low power and high speed applications.

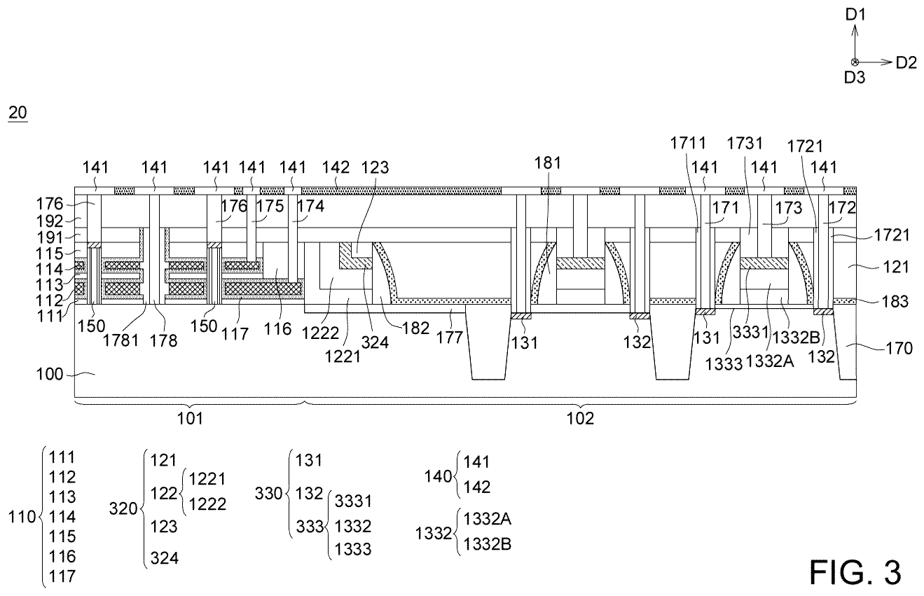

Referring to FIG. 3, FIG. 3 illustrates a schematic cross-sectional view of a memory device 20 according to another embodiment of the present disclosure. The differences between the memory device 20 and the memory device 10 of FIG. 1 are that the memory device 20 further includes a conductive portion 324, and the memory device 20 uses a conductive film 3331 instead of the conductive film 1331 of the memory device 10. The memory device 20 can include a substrate 100, at least one stacked structure 110, at least one stacked structure 320, at least one transistor 330, at least one metal routing layer 140 above the stacked structure 110 and the stacked structure 320, at least one channel pillar 150, a plurality of memory cells MS, a plurality of shallow trench isolations 170, at least one source contact structure 171, at least one drain contact structure 172, at least one gate contact structure 173, at least one conductive contact structure 174, at least one conductive contact structure 175, at least one channel contact structure 176, at least one dielectric film 177, at least one conductive pillar 178, at least one spacer 181, at least one spacer 182, a cover layer 183, at least one separation element 1711, at least one separation element 1721, at least one separation element 1731, at least one separation element 1781, an interlayer insulating layer 191 and an interlayer insulating layer 192.

The stacked structure 320 is in the peripheral region 102. The stacked structure 320 is disposed on the substrate 100 along the first direction.

The stacked structure 320 can be disposed on a side of the stacked structure 110 in the second direction D2 and/or the third direction D3. The stacked structure 320 may adjoin the stacked structure 110. The stacked structure 320 includes an insulating film 121, an extension portion 122, an insulating film 123 and the conductive portion 324. The conductive portion 324 is disposed between the insulating film 123 and the extension portion 122. The conductive portion 324 may extend and stacked along the first direction D1 and the second direction D2 on the extension portion 122. On the plane formed by the first direction D1 and the second direction D2, the conductive portion 324 may have a L-shaped section. The conductive portion 324 may extend on the plane formed by the second direction D2 and the third direction D3, and extend on the plane formed by the first direction D1 and the third direction D3. The transistor 330 is in peripheral region 102. The transistor 330 is in the stacked structure 320. The transistor 330 includes a source 131, a drain 132 and a gate 333 between the source 131 and the drain 132. The gate 333 includes a dielectric film 1333, a semiconductor film 1332 and a conductive film 3331 sequentially stacked along the first direction D1. The gate contact structure 173 can be disposed on the conductive film 3331. The gate contact structure may contact the conductive film 3331. The metal routing layer 140 can be electrically connected to the gate 333 of the transistor 330 through the gate contact structure 173. The material of the conductive film 3331 of the memory device 20 can be different from that of the conductive film 1331 of the memory device 10. The conductive portion 324 and the conductive film 3331 may include the same material or different materials. The transistor 330 can be a portion of the peripheral circuit of the memory device 20. The peripheral circuit of the memory device 20 may include other active and/or passive devices, such as transistors, diodes, capacitors and resistors. The circuit diagram and the threshold voltage distribution diagram of the memory device 20 are similar to those of the memory device 10.

In an embodiment, in the array region 101, the stacked structure 110 of the memory device 10 and the memory device 20 can only include two transistors (one data storage transistor and one selection transistor) stacked in the first direction D1 without including more transistors stacked along the first direction D1. In an embodiment, the memory device 10 and the memory device 20 may be memory devices with low power consumption, high performance, and low storage density (as compared with NAND type memory devices).

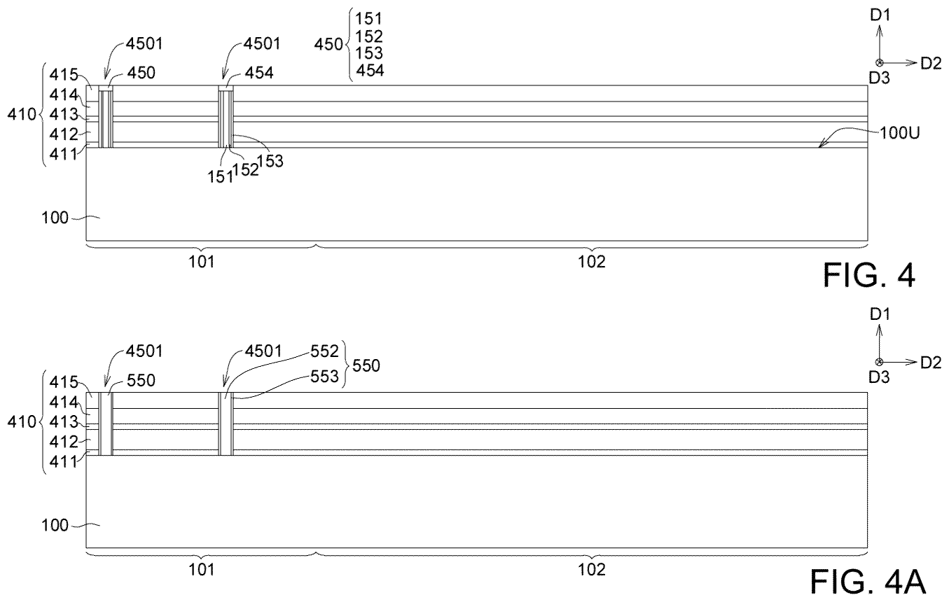

FIGS. 4 to 23 illustrate schematic cross-sectional views of structures at various stages of a method for manufacturing a memory device according to some embodiments of the present disclosure. The steps shown in FIGS. 4 to 23 can be performed in sequence or in other orders, the present disclosure is not limited thereto.

Referring to FIG. 4, FIG. 4 shows a schematic cross-sectional view of the structure at one stage of the method for manufacturing the memory device. A substrate 100 including an array region 101 and a peripheral region 102 is provided. A layer stack 410 is formed in the array region 101 and the peripheral region 102. The layer stack 410 is disposed on the substrate 100 along the first direction D1. The layer stack 410 can extend on a plane formed by the second direction D2 and the third direction D3 and across the array region 101 and the peripheral region 102. The layer stack 410 can include an insulating layer 411, a semiconductor material layer 412, an insulating layer 413, a dielectric layer 414 and an insulating layer 415. The insulating layer 411 can be disposed between the substrate 100 and the semiconductor material layer 412. The insulating layer 413 can be disposed between the semiconductor material layer 412 and the dielectric layer 414. The insulating layer 415 may be disposed on a side of the layer stack 410 away from the substrate 100. The insulating layer 411, the semiconductor material layer 412, the insulating layer 413, the dielectric layer 414 and the insulating layer 415 may be sequentially formed on the upper surface 100U of the substrate 100 through deposition processes to form the layer stack 410. The substrate 100 may include a semiconductor material such as doped or undoped monocrystalline silicon and doped or undoped polycrystalline silicon. In an embodiment, the substrate 100 includes doped or undoped monocrystalline silicon. The insulating layers 411, 413, and 415 may include insulating materials such as oxide. In an embodiment, the insulating layers 411, 413, and 415 include silicon oxide. The semiconductor material layer 412 may include semiconductor material such as doped or undoped polycrystalline silicon. The dielectric layer 414 may include a dielectric material such as nitride. In an embodiment, the dielectric layer 414 includes silicon nitride.

Then, at least one channel pillar 450 penetrating the layer stack 410 can be formed. The channel pillar 450 is disposed in the array region 101 and on the substrate 100. The channel pillars 450 may be separated from each other. The channel pillar 450 can include an insulating pillar 151, a channel layer 152, a charge storage layer 153 and a pad 454. The outer sidewall of the charge storage layer 153 may contact the insulating layer 411, the semiconductor material layer 412, the insulating layer 413, the dielectric layer 414 and the insulating layer 415. The pad 454 can be disposed on or contact the first end of the insulating pillar 151, the first end of the channel layer 152 and the first end of the charge storage layer 153. The second end of the insulating pillar 151 opposite to the first end of the insulating pillar 151, the second end of the channel layer 152 opposite to the first end of the channel layer 152, and the second end of the charge storage layer 153 opposite to the first end of the charge storage layer 153 may contact the substrate 100. The method for forming the channel pillar 450 may include: forming at least one hole 4501 in the layer stack 410 through an etching process, the hole 4501 may extend along the first direction D1, and a sidewall of the insulating layer 411, a sidewall of the semiconductor material layer 412, a sidewall of the insulating layer 413, a sidewall of the dielectric layer 414, a sidewall of the insulating layer 415, and the upper surface 100U of the substrate 100 can be exposed by the hole 4501; then, sequentially forming the charge storage layer 153, the channel layer 152 and the insulating pillar 151 in the hole 4501 through deposition processes; then, forming the pad 454 in the hole 4501 through a deposition process. In an embodiment, the deposition process for forming the pad 454 will cause the material of the pad 454 to be formed in the hole 4501 and above the insulating layer 415; the material of the pad 454 above the insulating layer 415 (it can also be understood as the material of the pad 454 outside the hole 4501) can be removed through an etching back process to form the pad 454.

The charge storage layer 153 may include a multilayer structure known from memory technologies, such as ONO (oxide-nitride-oxide), ONONO (oxide-nitride-oxide-nitride-oxide), ONONONO (oxide-nitride-oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), MA BE-SONOS (metal-high-k bandgap-engineered silicon-oxide-nitride-oxide-silicon), and combinations of those layers. The channel layer 152 may include a semiconductor material such as doped or undoped polycrystalline silicon. The insulating pillar 151 may include an insulating material such as an oxide. In an embodiment, the insulating pillar 151 includes silicon oxide. The pad 454 may include a semiconductor material such as doped or undoped polycrystalline silicon.

The structure of the channel pillar is not limited to that of the channel pillar 450 shown in FIG. 4. For example, the channel pillar can be a channel pillar 550 shown in FIG. 4A. The channel pillar 550 may include a channel layer 552 and a charge storage layer 553. The charge storage layer 553 may have a tubular shape and surround the channel layer 552. An outer sidewall of the charge storage layer 553 may contact the insulating layer 411, the semiconductor material layer 412, the insulating layer 413, the dielectric layer 414 and the insulating layer 415. The channel pillar 550 may contact the substrate 100. The method for forming the channel pillar 550 may include: forming the charge storage layer 553 in the hole 4501 through a deposition process, and then forming the channel layer 552 in the hole 4501 through a deposition process. The charge storage layer 553 may include a multilayer structure known from memory technologies, such as ONO (oxide-nitride-oxide), ONONO (oxide-nitride-oxide-nitride-oxide), ONONONO (oxide-nitride-oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), MA BE-SONOS (metal-high-k bandgap-engineered silicon-oxide-nitride-oxide-silicon), and combinations of those layers. The channel layer 552 may include a semiconductor material such as doped or undoped monocrystalline silicon, or doped or undoped polycrystalline silicon. In an embodiment, the channel layer 552 includes monocrystalline silicon formed by an epitaxial growth process.

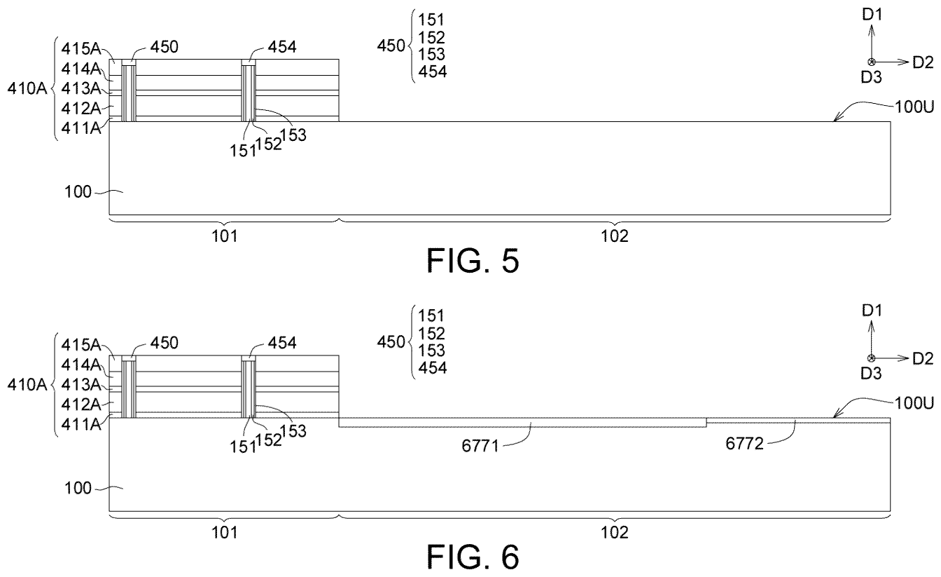

Referring to FIG. 5, FIG. 5 shows a schematic cross-sectional view of the structure at one stage of the method for manufacturing the memory device. A portion of the layer stack 410 is removed. Specifically, the portion of the layer stack 410 in the peripheral region 102 is removed, a portion of the layer stack 410 in the array region 101 is retained, and the retained portion is the layer stack 410A. The upper surface 100U of the substrate 100 in the peripheral region 102 is exposed. A portion of the insulating layer 411, a portion of the semiconductor material layer 412, a portion of the insulating layer 413, a portion of the dielectric layer 414 and a portion of the insulating layer 415 in the peripheral region 102 can be removed through an etching process; the retained portion of the insulating layer 411 is the insulating layer 411A; the retained portion of the semiconductor material layer 412 is the semiconductor material layer 412A; the retained portion of the insulating layer 413 is the insulating layer 413A; the retained portion of the dielectric layer 414 is the dielectric layer 414A; the retained portion of the insulating layer 415 is the insulating layer 415A. The insulating layer 411A, the semiconductor material layer 412, the insulating layer 413A, the dielectric layer 414A and the insulating layer 415A form the layer stack 410A.

Referring to FIG. 6, FIG. 6 shows a schematic cross-sectional view of the structure at one stage of the method for manufacturing the memory device. A dielectric film 6771 and a dielectric film 6772 is formed in the peripheral region 102. The heights of the dielectric films 6771 and 6772 in the first direction D1 may be different, but the present disclosure is not limited thereto. In the present embodiment, the height of the dielectric film 6771 in the first direction D1 is greater the height of the dielectric film 6772 in the first direction D1. The dielectric film 6771 can be used as a dielectric film (such as gate dielectric film) for high-voltage components. The dielectric film 6772 can be used as a dielectric film (such as gate dielectric film) for low-voltage components. The exposed portion of the substrate 100 may be subjected to one or more oxidation processes to form the dielectric film 6771 and the dielectric film 6772. In an embodiment, the oxidation processes for forming the dielectric film 6771 and the dielectric film 6772 are dry oxidation processes.

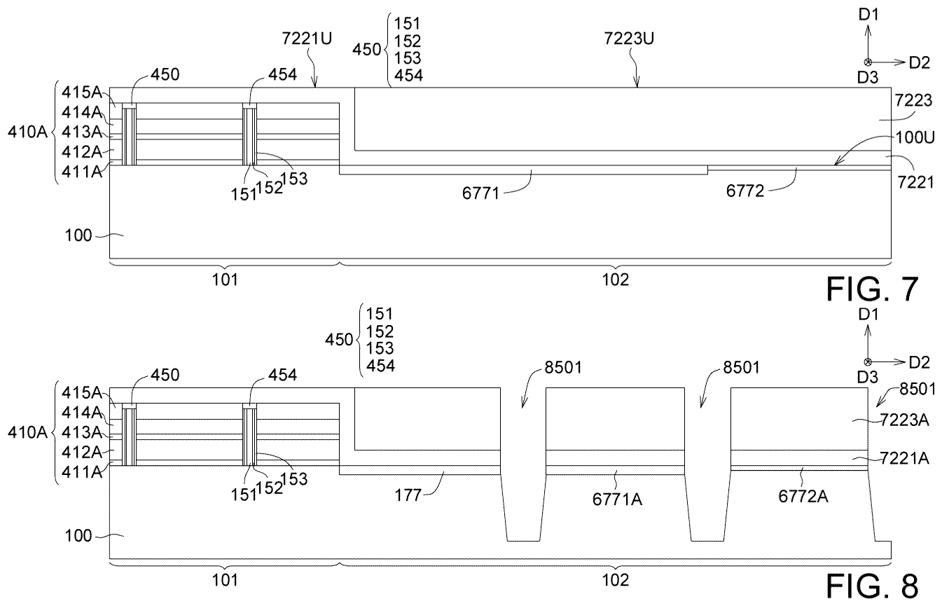

Referring to FIG. 7, FIG. 7 shows a schematic cross-sectional view of the structure at one stage of the method for manufacturing the memory device. A semiconductor layer 7221 and a filler 7223 are formed. The semiconductor layer 7221 may extend on the plane formed by the second direction D2 and the third direction D3 and across the array region 101 and the peripheral region 102. A portion of the semiconductor layer 7221 is on the layer stack 410A, and another portion of the semiconductor layer 7221 is on the dielectric films 6771 and 6772. The semiconductor layer 7221 may contact an upper surface of the layer stack 410A and a sidewall of the layer stack 410A. The semiconductor layer 7221 can contact the dielectric films 6771 and 6772. The filler 7223 is on semiconductor layer 7221. The filler 7223 is in the peripheral region 102. In the present embodiment, the upper surface 7221U of the semiconductor layer 7221 in the array region 101 and the upper surface 7223U of the filler 7223 in the peripheral region 102 may be coplanar (or may have substantially the same height in the first direction D1). The semiconductor layer 7221 may be formed on the layer stack 410A and the substrate 100 through a deposition process, and then the filler 7223 may be formed on the semiconductor layer 7221 through a deposition process. In an embodiment, the deposition process for forming the filler 7223 will cause the material of the filler 7223 to cover the semiconductor layer 7221 in the array region 101 and the peripheral region 102; a portion of the material of the filler 7223 can be removed through a polishing process to expose the upper surface 7221U of the semiconductor layer 7221 in the array region to form the filler 7223. The semiconductor layer 7221 may include a semiconductor material such as doped or undoped polycrystalline silicon. The filler 7223 may include insulating materials such as oxide. In an embodiment, the filler 7223 includes silicon oxide.

Referring to FIG. 8, FIG. 8 shows a schematic cross-sectional view of the structure at one stage of the method for manufacturing the memory device. At least one hole 8501 is formed in the peripheral region 102. The holes 8501 can be separated from each other. The hole 8501 may extend along the first direction D1. The hole 8501 may penetrate a filler 7223A, a semiconductor layer 7221A, a dielectric film 177, a dielectric film 6771A, a dielectric film 6772A and the substrate 100. A sidewall of the filler 7223A, a sidewall of the semiconductor layer 7221A, a sidewall of the dielectric film 6771A, a sidewall of the dielectric film 177, a sidewall of the dielectric film 6772A, a sidewall of the substrate 100 and a surface of the substrate 100 can be exposed by the hole 8501. The bottom of the hole 8501 may be lower than the upper surface 100U of the substrate 100. A portion of the filler 7223, a portion of the semiconductor layer 7221, a portion of the dielectric film 6771, a portion of the dielectric film 6772 and a portion of the substrate 100 can be removed through an etching process to form the hole 8501. The retained portion of the filler 7223 is the filler 7223A. The retained portion of the semiconductor layer 7221 is the semiconductor layer 7221A. The retained portion of the dielectric film 6771 can be divided into dielectric films 6771A and 177, and the hole 8501 separates the dielectric films 6771A and 177 from each other. The retained portion of dielectric film 6772 is the dielectric film 6772A.

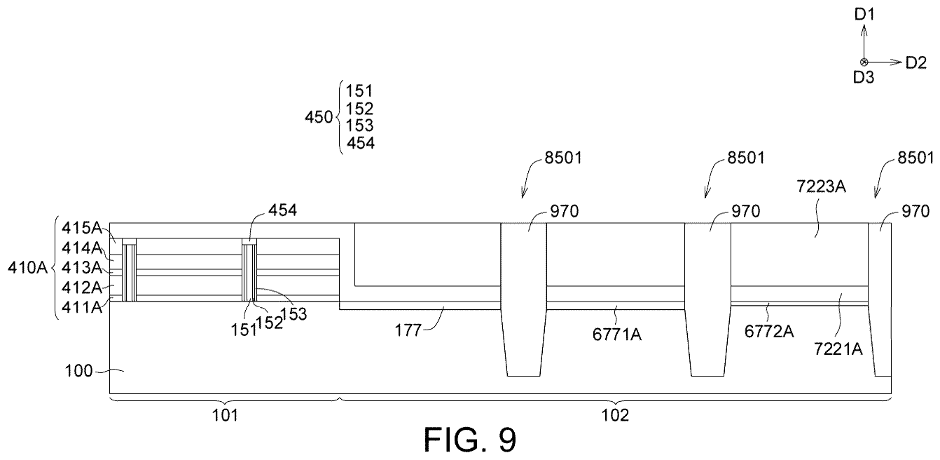

Referring to FIG. 9, FIG. 9 shows a schematic cross-sectional view of the structure at one stage of the method for manufacturing the memory device. At least one separation element 970 is formed. The separation element 970 can be formed in the hole 8501 through a deposition process. In an embodiment, the deposition process form forming the separation element 970 will cause the material of the separation element 970 to cover the semiconductor layer 7221A in the array region 101 and the filler 7223A in the peripheral region 102; the isolation element 970 can be formed by removing a portion of the material of the separation element 970 above the semiconductor layer 7221A and the filler 7223A through a polishing process while retaining a portion of the material of the separation element 970 in the hole 8501. The separation element 970 may include insulating materials such as oxide. In an embodiment, the separation element 970 includes silicon oxide.

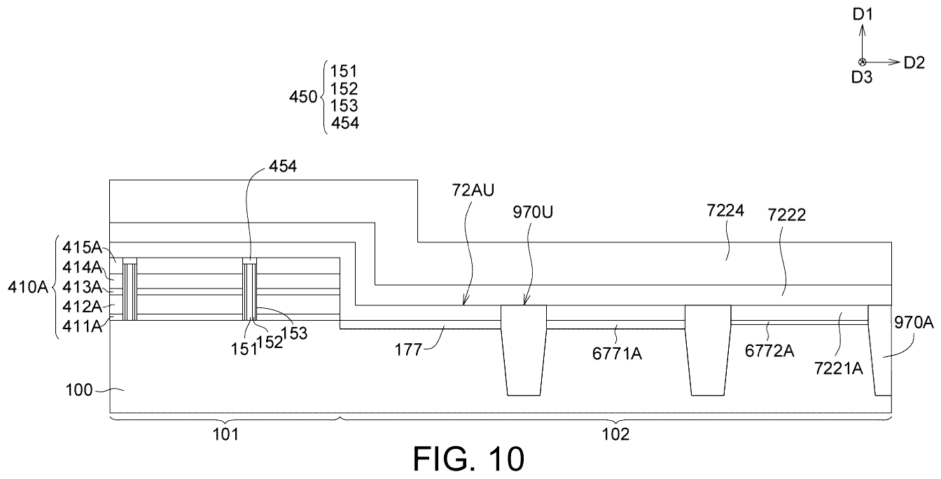

Referring to FIG. 10, FIG. 10 shows a schematic cross-sectional view of the structure at one stage of the method for manufacturing the memory device. At least one separation element 970A, a semiconductor layer 7222 and a gate oxide layer 7224 are formed. The separation element 970A may extend along the first direction D1 and penetrate the semiconductor layer 7221A, the dielectric film 6771A, the dielectric film 177, the dielectric film 6772A and the substrate 100. An upper surface 970U of the separation element 970A and an upper surface 72AU of the semiconductor layer 7221A may be coplanar. The semiconductor layer 7222 and the gate oxide layer 7224 may extend on the plane formed by the second direction D2 and the third direction D3 and across the array region 101 and the peripheral region 102. The semiconductor layer 7222 and the gate oxide layer 7224 may be disposed on the semiconductor layer 7221A. The semiconductor layer 7222 may be disposed between the gate oxide layer 7224 and the semiconductor layer 7221A. The filler 7223A and a portion of the separation element 970 higher than the upper surface 72AU of the semiconductor layer 7221A can be removed through an etching back process, and the retained portion of the separation element 970 is the separation element 970A. After the separation element 970A is formed, the semiconductor layer 7222 and the gate oxide layer 7224 can be sequentially formed on the semiconductor layer 7221A through deposition processes. The semiconductor layer 7222 and the gate oxide layer 7224 may be conformally formed on the semiconductor layer 7221A. The semiconductor layer 7222 may include a semiconductor material such as doped or undoped polycrystalline silicon. The gate oxide layer 7224 may include an insulating material such as an oxide. In an embodiment, the gate oxide layer 7224 includes silicon oxide.

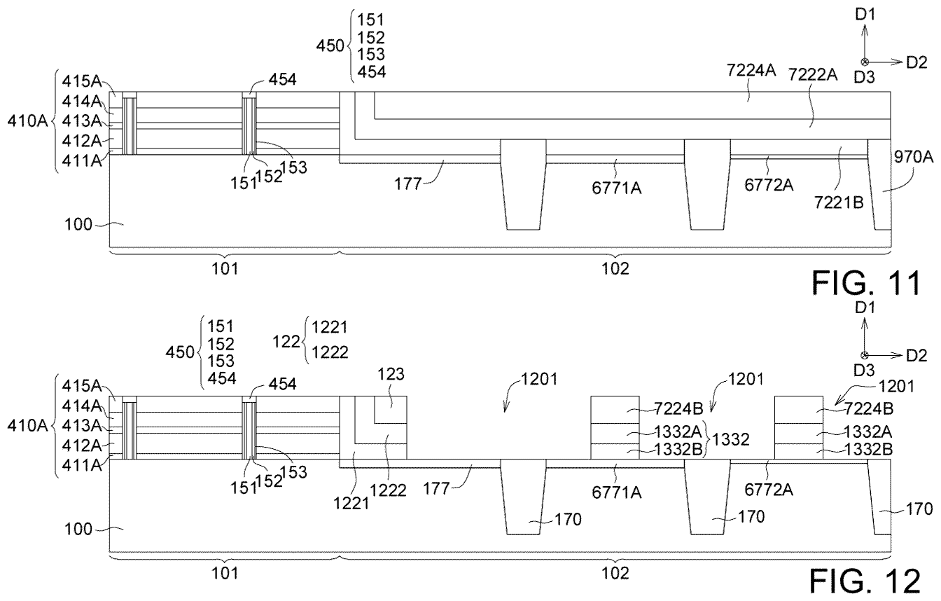

Referring to FIG. 11, FIG. 11 shows a schematic cross-sectional view of the structure at one stage of the method for manufacturing the memory device. A semiconductor layer 7221B, a semiconductor layer 7222A and a gate oxide layer 7224A are formed. An upper surface of semiconductor layer 7221B, an upper surface of the semiconductor layer 7222A, an upper surface of the gate oxide layer 7224A, and an upper surface of the layer stack 410A may be coplanar. A portion of the semiconductor layer 7221A higher than the upper surface of the layer stack 410A, a portion of the semiconductor layer 7222 higher than the upper surface of the layer stack 410A, and a portion of the gate oxide layer 7224 higher than the upper surface of the layer stack 410A can be removed by an etching process. The retained portion of the semiconductor layer 7221A is the semiconductor layer 7221B. The retained portion of the semiconductor layer 7222 is the semiconductor layer 7222A. The retained portion of the gate oxide layer 7224 is the gate oxide layer 7224A.

Referring to FIG. 12, FIG. 12 shows a schematic cross-sectional view of the structure at one stage of the method for manufacturing the memory device. In the peripheral region 102, an extension portion 122 including a semiconductor layer 1221 and a semiconductor layer 1222, an insulating film 123, a semiconductor film 1332 including a semiconductor material film 1332A and a semiconductor material film 1332B, a gate oxide layer 7224B, and shallow trench isolations 170 are formed. At least one hole 1201 is formed in the peripheral region 102. The holes 1201 can be separated from each other. One of the holes 1201 may expose an upper surface of the dielectric film 177, an upper surface of the shallow trench isolation 170, an upper surface of the dielectric film 6771A, a sidewall of the extension portion 122, a sidewall of the insulating film 123, a sidewall of the semiconductor film 1332, and a sidewall of the gate oxide layer 7224B. One of the holes 1201 may expose an upper surface of the dielectric film 6771A, an upper surface of the shallow trench isolation 170, an upper surface of the dielectric film 6772A, sidewalls of the semiconductor film 1332, and sidewalls of the gate oxide layer 7224B. The upper surfaces of shallow trench isolations 170, the upper surface of dielectric film 177, the upper surface of dielectric film 6771A, and the upper surface of dielectric film 6772A may be coplanar. The extension portion 122 may adjoin the layer stack 410A. The semiconductor layer 1222 of the extension portion 122 may be between the semiconductor layer 1221 and the insulating film 123. The extension portion 122 may be disposed at the boundary of the peripheral region 102, or the extension portion 122 may serve as a boundary between the array region 101 and the peripheral region 102.

The hole 1201 may be formed by removing a portion of the separation element 970A, a portion of the semiconductor layer 7221B, a portion of the semiconductor layer 7222A, and a portion of the gate oxide layer 7224A through an etching process. The retained portion of the separation element 970A is the shallow trench isolation 170. The retained portion of the semiconductor layer 7221B can be divided into the semiconductor layer 1221 and the semiconductor material film 1332B. The retained portion of the semiconductor layer 7222A can be divided into the semiconductor layer 1222 and the semiconductor material film 1332A. The retained portion of the gate oxide layer 7224A can be divided into the insulating film 123 and the gate oxide layer 7224B. The hole 1201 can separate the semiconductor layer 1221 from the semiconductor material film 1332B. The hole 1201 can separate the semiconductor layer 1222 from the semiconductor material film 1332A.

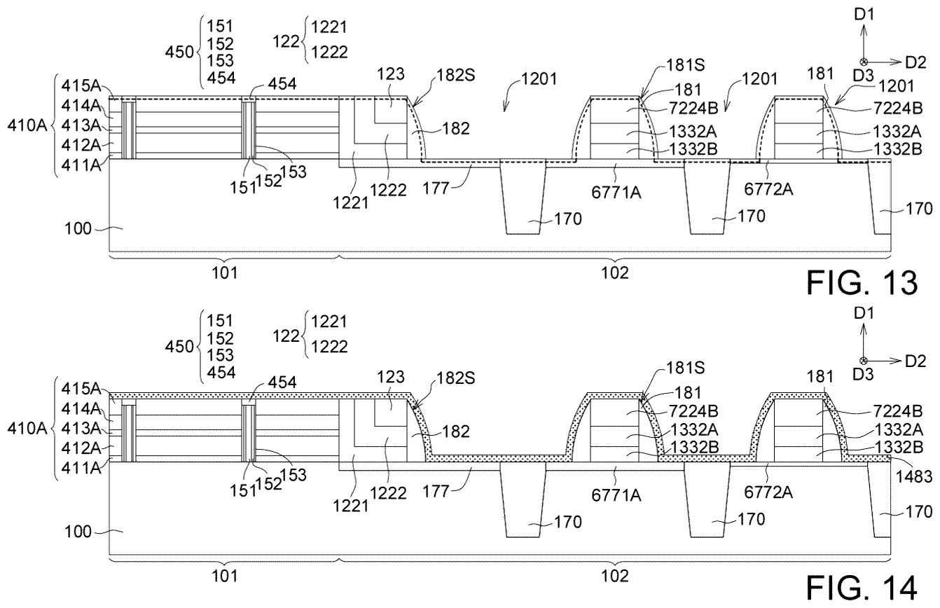

Referring to FIG. 13, FIG. 13 shows a schematic cross-sectional view of the structure at one stage of the method for manufacturing the memory device. Spacers 181 and at least one spacer 182 are formed in the peripheral region 102. The spacer 181 and the spacer 182 are in the holes 1201. FIG. 13 illustrates the spacer 181 and the spacer 182 as having arc-shaped sidewalls 181S and 182S respectively, but the present disclosure is not limited thereto. The spacer 181 may adjoin the sidewall of the semiconductor film 1332 and the sidewall of the gate oxide layer 7224B. The spacer 182 may adjoin the sidewall of the extension portion 122 and the sidewall of the insulating film 123. The spacers 181 and the spacer 182 may be separated from each other. The spacer 181 and the spacer 182 may include insulating materials such as oxide or nitride. In an embodiment, the spacer 181 and the spacer 182 include silicon oxide or silicon nitride. The spacers 181 and the spacer 182 may include the same material or different materials. Insulating materials (i.e. the materials of the spacer 181 and the spacer 182) may be formed in the holes 1201 through a deposition process, and the insulating materials may fill the holes 1201. Then, a portion of the insulating materials may be removed through an etching process; the retained portion of the insulating materials can be divided into the spacer 181 and the spacer 182.

In an embodiment, after the spacer 181 and the spacer 182 are formed, an ion implantation process can be performed to the surface of the structure shown in FIG. 13 (such as the surface marked with a dotted line in FIG. 13) to introduce N-type or P-type dopants to the surface of the structure shown in FIG. 13. The ion implantation process can be performed simultaneously to the structure in the array region 101 and the structure in the peripheral region 102.

Referring to FIG. 14, FIG. 14 shows a schematic cross-sectional view of the structure at one stage of the method for manufacturing the memory device. A cover layer 1483 is formed. The cover layer 1483 may extend on the plane formed by the second direction D2 and the third direction D3 and across the array region 101 and the peripheral region 102. The cover layer 1483 may cover the upper surface of the layer stack 410A, the upper surface of the semiconductor layer 1221, the upper surface of the semiconductor layer 1222, the upper surface of the insulating film 123, the sidewall 182S of the spacer 182, the upper surface of the dielectric film 177, the upper surfaces of the shallow trench isolations 170, the upper surface of the dielectric film 6771A, the sidewalls 181S of the spacers 181, the upper surfaces of the gate oxide layers 7224B, and the upper surface of dielectric film 6772A. The cover layer 1483 may be conformally formed on the layer stack 410A, the extension portion 122, the insulating film 123, the spacer 182, the dielectric film 177, the shallow trench isolations 170, the dielectric film 6771A, the spacers 181, and the gate oxide layers 7224B through a deposition process. The cover layer 1483 may include a dielectric material such as nitride.

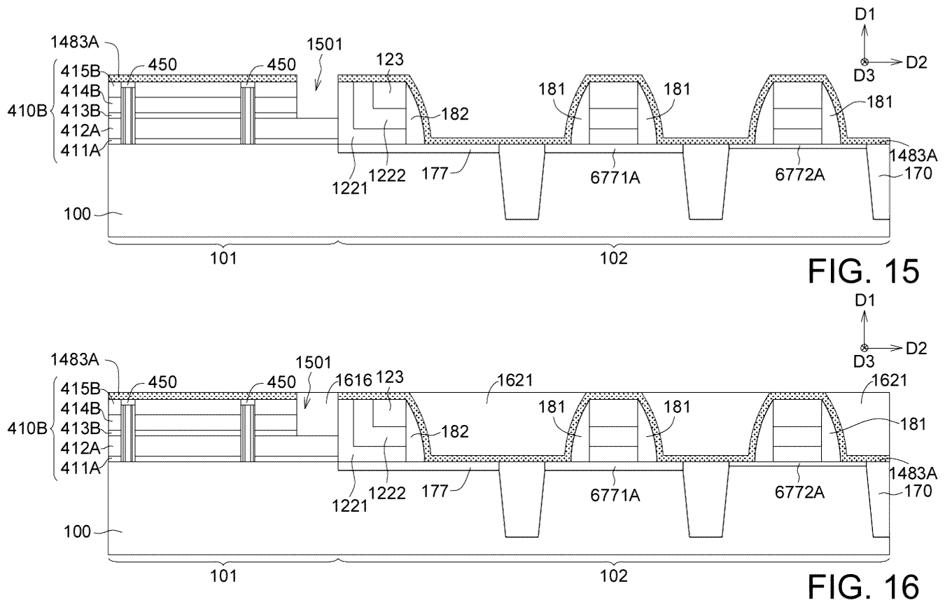

Referring to FIG. 15, FIG. 15 shows a schematic cross-sectional view of the structure at one stage of the method for manufacturing the memory device. A hole 1501 is formed in the array region 101. The hole 1501 may penetrate a cover layer 1483A, an insulating layer 415B, a dielectric layer 414B and an insulating layer 413B. The hole 1501 may expose a sidewall of the cover layer 1483A, a sidewall of the insulating layer 415B, a sidewall of the dielectric layer 414B, a sidewall of the insulating layer 413B, an upper surface of the semiconductor material layer 412A, and a sidewall of the semiconductor layer 1221. The hole 1501 may be disposed at the boundary of the array region 101. The hole 1501 may be formed by removing a portion of the cover layer 1483, a portion of the insulating layer 415A, a portion of the dielectric layer 414A, and a portion of the insulating layer 413A through an etching process. The retained portion of the cover layer 1483 is the cover layer 1483A. The retained portion of the insulating layer 415A is the insulating layer 415B. The retained portion of the dielectric layer 414A is the dielectric layer 414B. The retained portion of the insulating layer 413A is the insulating layer 413B. The insulating layer 411A, the semiconductor material layer 412A, the insulating layer 413B, the dielectric layer 414B and the insulating layer 415B form a layer stack 410B.

Referring to FIG. 16, FIG. 16 shows a schematic cross-sectional view of the structure at one stage of the method for manufacturing the memory device. An insulating layer 1616 is formed in the array region 101. An insulating film 1621 is formed in the peripheral region 102. The insulating layer 1616 is disposed in the hole 1501. The insulating film 1621 is disposed on the cover layer 1483A. The insulating layer 1616 and the insulating film 1621 can be formed by a deposition process and a polishing process. The insulating layer 1616 and the insulating film 1621 may include insulating materials such as oxide. The insulating layer 1616 and the insulating film 1621 may include the same material or different materials. In an embodiment, the insulating layer 1616 and the insulating film 1621 include silicon oxide.

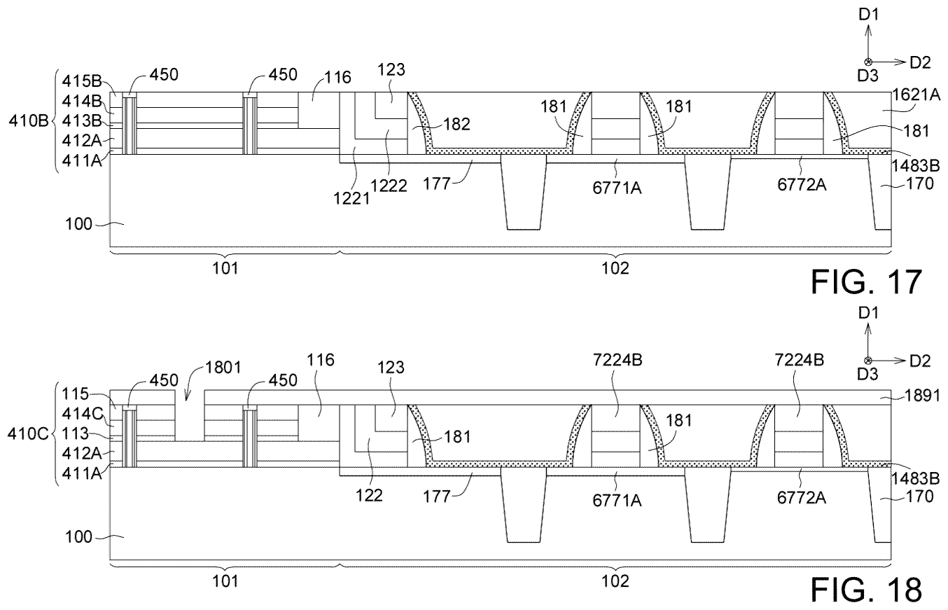

Referring to FIG. 17, FIG. 17 shows a schematic cross-sectional view of the structure at one stage of the method for manufacturing the memory device. An insulating film 1621A, a cover layer 1483B and an insulating layer 116 are formed. The insulating film 1621A and the cover layer 1483B are in the peripheral region 102. The insulating layer 116 is in array region 101. Portions of the cover layer 1483A above an upper surface of the layer stack 410B, an upper surface of the extension portion 122, an upper surface of the insulating film 123, and the upper surfaces of the gate oxide layers 7224B, and portions of the insulating layer 1616 and the insulating film 1621 higher than the upper surface of the layer stack 410B can be removed through an etching back process to form the structure as shown in FIG. 17. The retained portion of the cover layer 1483A is the cover layer 1483B. The retained portion of the insulating layer 1616 is the insulating layer 116. The retained portion of the insulating film 1621 is the insulating film 1621A.

In other embodiments, the step shown in FIG. 17 can be omitted.

Referring to FIG. 18, FIG. 18 shows a schematic cross-sectional view of the structure at one stage of the method for manufacturing the memory device. An interlayer insulating layer 1891 and a hole 1801 penetrating the interlayer insulating layer 1891 are formed. The interlayer insulating layer 1891 may extend on the plane formed by the second direction D2 and the third direction D3 and across the array region 101 and the peripheral region 102. The hole 1801 can be disposed in the array region 101. The hole 1801 may extend along the first direction D1 and penetrate an insulating layer 115, a dielectric layer 414C and an insulating layer 113. A sidewall of the interlayer insulating layer 1891, a sidewall of the insulating layer 115, a sidewall of the dielectric layer 414C, a sidewall of the insulating layer 113 and an upper surface of the semiconductor material layer 412A can be exposed by the hole 1801. The hole 1801 may be disposed between the channel pillars 450. The interlayer insulating layer 1891 may be formed above the layer stack 410B, the gate oxide layer 7224B and the insulating film 1621A through a deposition process; then, a portion of the interlayer insulating layer 1891, a portion of the insulating layer 415B, a portion of the dielectric layer 414B, and a portion of the insulating layer 413B may be removed to form the hole 1801. The retained portion of the insulating layer 415B is the insulating layer 115. The retained portion of the dielectric layer 414B is the dielectric layer 414C. The retained portion of the insulating layer 413B is the insulating layer 113. The insulating layer 411A, the semiconductor material layer 412A, the insulating layer 113, the dielectric layer 414C and the insulating layer 115 form a layer stack 410C. The interlayer insulating layer 1891 may include an insulating material such as oxide. In an embodiment, the interlayer insulating layer 1891 includes silicon oxide.

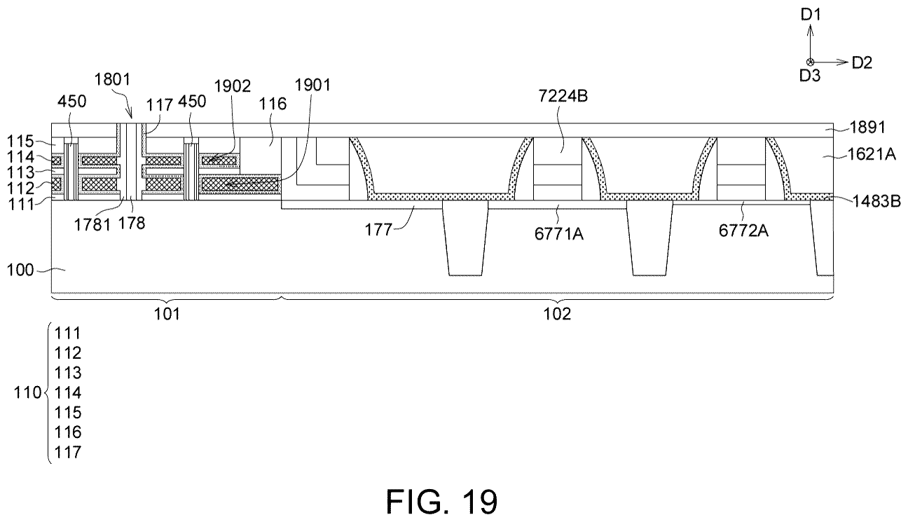

Referring to FIG. 19, FIG. 19 shows a schematic cross-sectional view of the structure at one stage of the method for manufacturing the memory device. In the array region 101, a stacked structure 110 including an insulating layer 111, a conductive layer 112, an insulating layer 113, a conductive layer 114, an insulating layer 115, an insulating layer 116 and a barrier layer 117, a conductive pillar 178 penetrating the stacked structure 110, and a separation element 1781 between the conductive pillar 178 and the barrier layer 117 are formed. The conductive layer 112 and conductive layer 114 may include conductive materials such as metal. The conductive layer 112 and conductive layer 114 may include the same material or different materials. In an embodiment, the conductive layer 112 and the conductive layer 114 include tungsten. The barrier layer 117 may include a multilayer structure, such as an oxide/nitride/oxide (ONO) multilayer structure. The conductive pillar 178 may include a conductive material such as metal. In an embodiment, the conductive pillar 178 includes tungsten. The separation element 1781 may include an insulating material such as an oxide. In an embodiment, the separation element 1781 includes silicon oxide.

The dielectric layer 414C and the semiconductor material layer 412A may be removed through the hole 1801 through an etching process to form a space 1902 between the insulating layer 113 and the insulating layer 115, and a space 1901 between the insulating layer 113 and the insulating layer 411A. Then, the barrier layer 117 may be formed in the space 1901, in the space 1902, on the sidewall of the insulating layer 113 exposed by the hole 1801, on the sidewall of the insulating layer 115 exposed by the hole 1801, and on the sidewall of the interlayer insulating layer 1891 exposed by the hole 1801 through a deposition process. Then, a conductive material may be formed in the remaining space of space 1902 (that is, the space that is not filled by barrier layer 117), the remaining space of space 1901 (that is, the space that is not filled by barrier layer 117), and the remaining space of hole 1801 (that is, the space that is not filled by barrier layer 117) through a deposition process. Then, a portion of the conductive material in the hole 1801 may be removed through an etching back process, and a portion of the insulating layer 411A may be removed through an etching process to expose the substrate 100; the retained portion of the insulating layer 411A is the insulating layer 111. The retained portion of the conductive material in the space 1902 is the conductive layer 114. The retained portion of the conductive material in the space 1901 is the conductive layer 112. The sidewall of the conductive layer 114 exposed by the hole 1801 may be recessed relative to the sidewall of the barrier layer 117 exposed by the hole 1801 to form a recess. The sidewall of the conductive layer 112 exposed by the hole 1801 may be recessed relative to the sidewall of the barrier layer 117 exposed by the hole 1801 to form a recess. Then, the conductive pillar 178 and the separation element 1781 may be formed in the hole 1801 through a deposition process and an etching process. A portion of the separation element 1781 may be formed in the recesses.

In an embodiment, after the conductive pillar 178 and the separation element 1781 are formed, a polishing process can be performed to make the upper surface of the conductive pillar 178, the upper surface of the separation element 1781, the upper surface of the barrier layer 117 and the upper surface of the interlayer insulating layer 1891 coplanar.

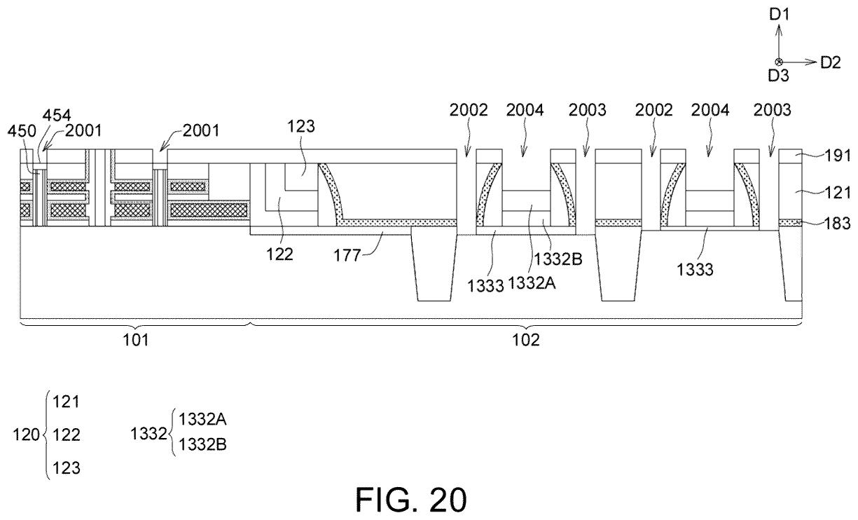

Referring to FIG. 20, FIG. 20 shows a schematic cross-sectional view of the structure at one stage of the method for manufacturing the memory device. An interlayer insulating layer 191 is formed. A portion of the interlayer insulating layer 191 is in the array region 101, and another portion of the interlayer insulating layer 191 is in the peripheral region 102. Holes 2001 penetrating the interlayer insulating layer 191 are formed in the array region 101. Holes 2002 and 2003 penetrating the interlayer insulating layer 191, the insulating film 121, and the cover layer 183 are formed in the peripheral region 102. Holes 2004 penetrating the interlayer insulating layer 191 and the insulating film 121 are formed in the peripheral region 102. The number and location of holes 2001 may correspond to the number and location of channel pillars 450. An upper surface of the channel pillar 450 (i.e. the upper surface of the pad 454) and a sidewall of the interlayer insulating layer 191 may be exposed by the hole 2001. The holes 2002 and 2003 may be disposed on opposite sides of the hole 2004. The number and location of the holes 2004 may correspond to the number and location of the semiconductor film 1332. The holes 2002 and 2003 may extend to the upper surface of the substrate 100 along the first direction D1. The holes 2002 and 2003 may expose the substrate 100. The hole 2004 may expose the semiconductor material film 1332A of the semiconductor film 1332.

A portion of the interlayer insulating layer 1891 may be removed through an etching process to form the hole 2001. A portion of the interlayer insulating layer 1891, a portion of the insulating film 1621A, a portion of the cover layer 1483B, a portion of the dielectric film 6771A, and a portion of the dielectric film 6772A may be removed through an etching process to form the holes 2002 and 2003. A portion of the interlayer insulating layer 1891 and the gate oxide layer 7224B may be removed through an etching process to form the hole 2004. After performing the etching process to form the holes 2001 to 2004, the retained portion of the interlayer insulating layer 1891 is the interlayer insulating layer 191, the retained portion of the insulating film 1621A is the insulating film 121, the retained portion of the cover layer 1483B is the cover layer 183, and the retained portions of the dielectric film 6771A and the dielectric film 6772A are the dielectric films 1333. The insulating film 121, the extension portion 122 and the insulating film 123 can form a stacked structure 120.

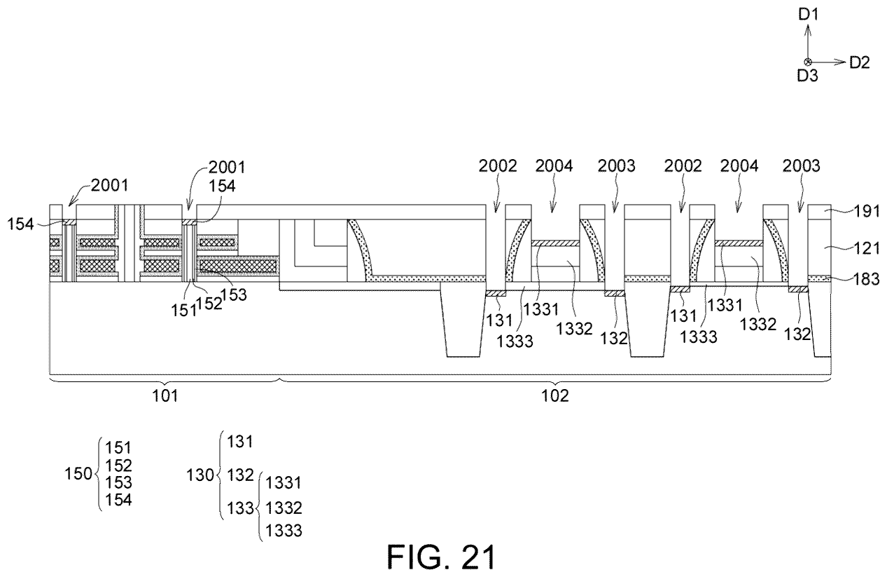

Referring to FIG. 21, FIG. 21 shows a schematic cross-sectional view of the structure at one stage of the method for manufacturing the memory device. At least one transistor 130 is formed in the peripheral region 102. A channel pillar 150 is formed in the array region 101. A metal material can be formed in the holes 2001 to 2004 through a deposition process, and then a rapid thermal process (RTP) can be used to react the metal material (such as titanium, tungsten, cobalt or nickel) with the semiconductor material (such as silicon) below it to form the pad 154 in the hole 2001, the source 131 in the hole 2002, the drain 132 in the hole 2003, and the conductive film 1331 in the hole 2004. In the present embodiment, the pad 454 reacts with the metal material and becomes the pad 154, a part of the substrate 100 reacts with the metal material to form the source 131, a portion of the substrate 100 reacts with the metal material to form the drain 132, and a portion of the semiconductor film 1332 reacts with the metal material to form the conductive film 1331. The conductive film 1331, the semiconductor film 1332 and the dielectric film 1333 can form the gate 133. The source 131, the drain 132 and the gate 133 can form the transistor 130. The insulating pillar 151, the channel layer 152, the charge storage layer 153 and the pad 154 can form the channel pillar 150.

In an embodiment, after the pad 154 and the transistor 130 are formed, unreacted metal material may be removed by an etching process. The pad 154, the source 131, the drain 132 and the conductive film 1331 may include metal silicide, such as titanium silicide, tungsten silicide, cobalt silicide or nickel silicide. In an embodiment, the pad 154, the source 131, the drain 132 and the conductive film 1331 include cobalt silicide.

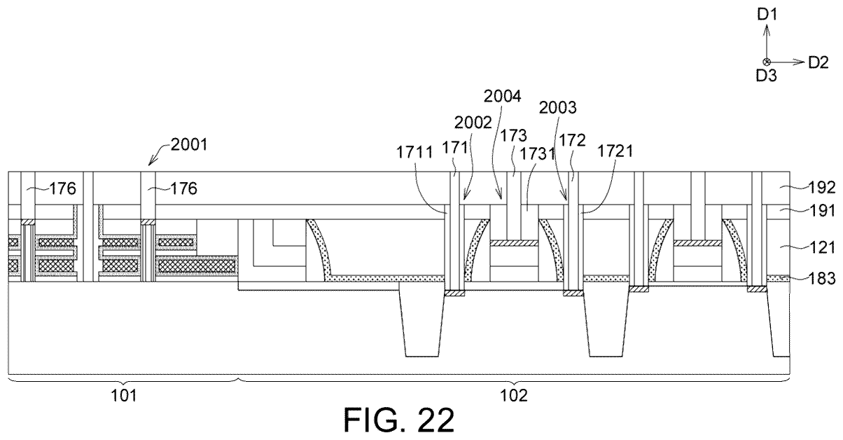

Referring to FIG. 22, FIG. 22 shows a schematic cross-sectional view of the structure at one stage of the method for manufacturing the memory device. An interlayer insulating layer 192 is formed. A portion of the interlayer insulating layer 192 is in the array region 101, and another portion of the interlayer insulating layer 192 is in the peripheral region 102. A channel contact structure 176 is formed in the array region 101. A source contact structure 171, a separation element 1711 on the sidewall of the source contact structure 171, a drain contact structure 172, a separation element 1721 on the sidewall of the drain contact structure 172, a gate contact structure 173, and a separation element 1731 on the sidewall of the gate contact structure 173 are formed in the peripheral region 102.

The separation element 1711 may be formed in the hole 2002, the separation element 1721 may be formed in the hole 2003, and the separation element 1731 may be formed in the hole 2004 through a deposition process. Next, the interlayer insulating layer 192 may be formed above the interlayer insulating layer 191 through a deposition process. Then, the channel contact structure 176 penetrating the interlayer insulating layers 191 and 192, the source contact structure 171 penetrating the interlayer insulating layer 192 and the separation element 1711, the drain contact structure 172 penetrating the interlayer insulating layer 192 and the separation element 1721, and the gate contact structure 173 penetrating the interlayer insulating layer 192 and the separation element 1731 may be formed by an etching process and a deposition process. The interlayer insulating layer 192 may include an insulating material such as an oxide. In an embodiment, the interlayer insulating layer 192 includes silicon oxide. The channel contact structure 176, the source contact structure 171, the drain contact structure 172 and the gate contact structure 173 may include conductive materials such as metal. The channel contact structure 176, the source contact structure 171, the drain contact structure 172 and the gate contact structure 173 may include the same material or different materials. In an embodiment, the channel contact structure 176, the source contact structure 171, the drain contact structure 172 and the gate contact structure 173 include tungsten. The separation elements 1711, 1721 and 1731 may include insulating materials such as an oxide. In an embodiment, the separation elements 1711, 1721 and 1731 include silicon oxide.

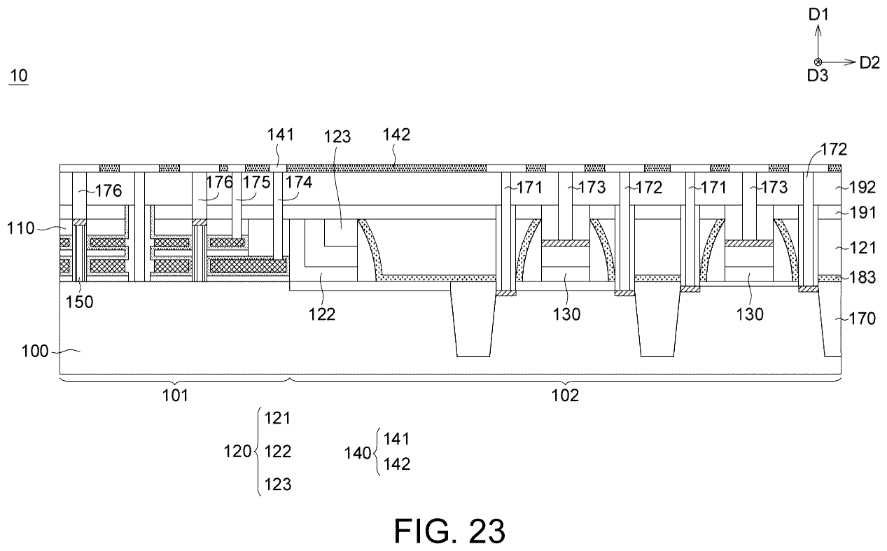

Referring to FIG. 23, FIG. 23 shows a schematic cross-sectional view of the structure at one stage of the method for manufacturing the memory device. A conductive contact structure 175 and a conductive contact structure 174 are formed. A metal routing layer 140 including an insulating material 142 and conductive lines 141 are formed on the interlayer insulating layer 192. The conductive lines 141 may be electrically isolated from each other by the insulating material 142. The positions of the conductive lines 141 may correspond to the positions of the channel contact structure 176, the conductive pillar 178, the conductive contact structure 175, the conductive contact structure 174, the source contact structure 171, the drain contact structure 172 and the gate contact structure 173 to form electrical connections. The insulating material 142 may include an oxide such as silicon oxide. The conductive line may include conductive material such as metal. In an embodiment, the conductive line 141 includes tungsten. The conductive contact structure 175 and the conductive contact structure 174 may be formed in the array region 101 through an etching process and a deposition process. After the conductive contact structure 175 and the conductive contact structure 174 are formed, the metal routing layer 140 may be formed in the array region 101 and the peripheral region 102 through an etching process and a deposition process. In an embodiment, the steps shown in FIGS. 22 and 23 can be performed in the back-end-of-the-line (BEOL) process of the semiconductor manufacturing process.

In an embodiment, through the method schematically illustrated in FIGS. 4 to 23, a memory device 10 as shown FIG. 1 is provided.

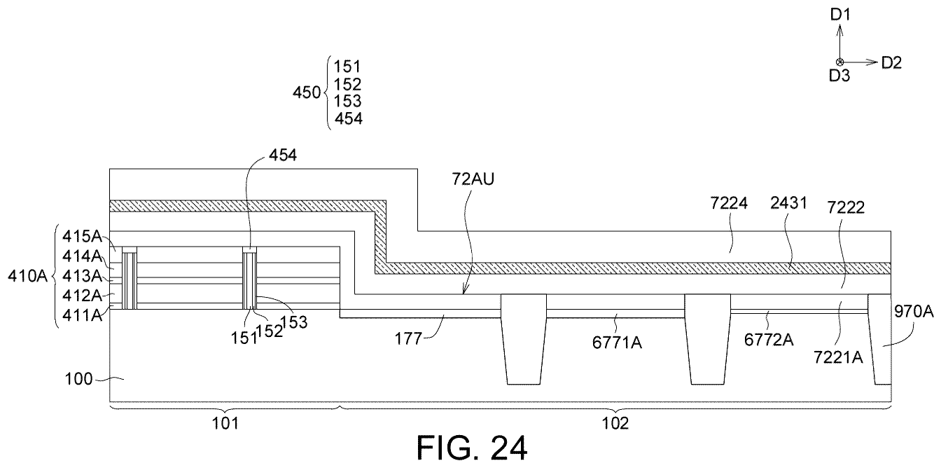

FIGS. 24 to 37 illustrate schematic cross-sectional views of structures at various stages of a method for manufacturing a memory device according to some embodiments of the present disclosure. The steps shown in FIGS. 24 to 37 can be performed in sequence or in other orders, the present disclosure is not limited thereto. In some embodiments, the manufacturing steps shown in FIGS. 24 to 37 can be performed after the manufacturing steps shown in FIGS. 4 to 9.

Referring to FIG. 24, FIG. 24 shows a schematic cross-sectional view of the structure at one stage of the method for manufacturing the memory device. At least one separation element 970A, a semiconductor layer 7222, a conductive film 2431 and a gate oxide layer 7224 are formed. The semiconductor layer 7222, the conductive film 2431 and the gate oxide layer 7224 may extend on the plane formed by the second direction D2 and the third direction D3 and across the array region 101 and the peripheral region 102. The semiconductor layer 7222, the conductive film 2431 and the gate oxide layer 7224 may be disposed on the semiconductor layer 7221A. The semiconductor layer 7222 may be disposed between the conductive film 2431 and the semiconductor layer 7221A. The conductive film 2431 may be disposed between the gate oxide layer 7224 and the semiconductor layer 7222. The filler 7223A and a portion of the separation element 970 higher than the upper surface 72AU of the semiconductor layer 7221A may be removed through an etching back process, and the retained portion of the separation element 970 is the separation element 970A. After the separation element 970A is formed, the semiconductor layer 7222, the conductive film 2431 and the gate oxide layer 7224 may be sequentially formed on the semiconductor layer 7221A through deposition processes. The semiconductor layer 7222, the conductive film 2431 and the gate oxide layer 7224 may be conformally formed on the semiconductor layer 7221A. The conductive film 2431 may include a conductive material such as metal silicide. The metal silicide may be, for example, titanium silicide, tungsten silicide, cobalt silicide or nickel silicide. In an embodiment, the conductive film 2431 includes tungsten silicide.

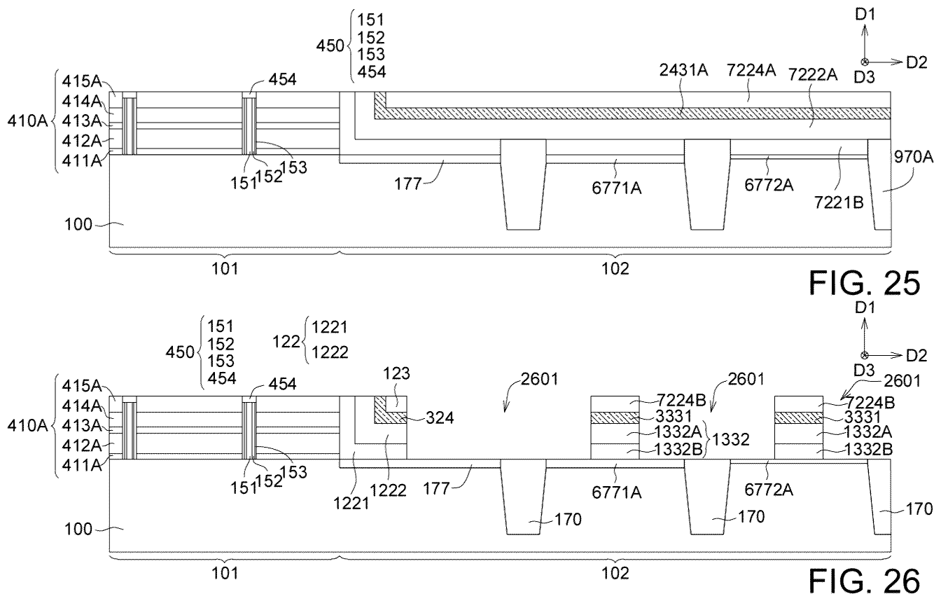

Referring to FIG. 25, FIG. 25 shows a schematic cross-sectional view of the structure at one stage of the method for manufacturing the memory device. A semiconductor layer 7221B, a semiconductor layer 7222A, the conductive film 2431A and a gate oxide layer 7224A are formed. An upper surface of semiconductor layer 7221B, an upper surface of the semiconductor layer 7222A, an upper surface of the conductive film 2431A, an upper surface of the gate oxide layer 7224A, and an upper surface of the layer stack 410A may be coplanar. A portion of the semiconductor layer 7221A higher than the upper surface of the layer stack 410A, a portion of the semiconductor layer 7222 higher than the upper surface of the layer stack 410A, a portion of the conductive film 2431 higher than the upper surface of the layer stack 410A, and a portion of the gate oxide layer 7224 higher than the upper surface of the layer stack 410A may be removed by an etching process. The retained portion of the semiconductor layer 7221A is the semiconductor layer 7221B. The retained portion of the semiconductor layer 7222 is the semiconductor layer 7222A. The retained portion of the conductive film 2431 is the conductive film 2431A. The retained portion of the gate oxide layer 7224 is the gate oxide layer 7224A.

Referring to FIG. 26, FIG. 26 shows a schematic cross-sectional view of the structure at one stage of the method for manufacturing the memory device. In the peripheral region 102, an extension portion 122 including a semiconductor layer 1221 and a semiconductor layer 1222, a conductive portion 324, an insulating film 123, a semiconductor film 1332 including a semiconductor material film 1332A and a semiconductor material film 1332B, a conductive film 3331, a gate oxide layer 7224B, and shallow trench isolations 170 are formed. At least one hole 2601 is formed in the peripheral region 102. The holes 2601 can be separated from each other. One of the holes 2601 may expose an upper surface of the dielectric film 177, an upper surface of the shallow trench isolation 170, an upper surface of the dielectric film 6771A, a sidewall of the extension portion 122, a sidewall of the conductive portion 324, a sidewall of the insulating film 123, a sidewall of the semiconductor film 1332, a sidewall of the conductive film 3331, and a sidewall of the gate oxide layer 7224B. One of the holes 2601 may expose an upper surface of the dielectric film 6771A, an upper surface of the shallow trench isolation 170, an upper surface of the dielectric film 6772A, sidewalls of the semiconductor film 1332, sidewalls of the conductive film 3331 and sidewalls of the gate oxide layer 7224B. The upper surfaces of shallow trench isolations 170, the upper surface of dielectric film 177, the upper surface of dielectric film 6771A, and the upper surface of dielectric film 6772A may be coplanar. The semiconductor layer 1222 of the extension portion 122 may be between the semiconductor layer 1221 and the conductive portion 324. The conductive portion 324 may be disposed between the semiconductor layer 1222 and the insulating film 123. The extension portion 122 may be disposed at the boundary of the peripheral region 102, or the extension portion 122 may serve as a boundary between the array region 101 and the peripheral region 102.

The hole 2601 may be formed by removing a portion of the separation element 970A, a portion of the semiconductor layer 7221B, a portion of the semiconductor layer 7222A, a portion of the conductive film 2431A and a portion of the gate oxide layer 7224A through an etching process. The retained portion of the separation element 970A is the shallow trench isolation 170. The retained portion of the semiconductor layer 7221B can be divided into the semiconductor layer 1221 and the semiconductor material film 1332B. The retained portion of the semiconductor layer 7222A can be divided into the semiconductor layer 1222 and the semiconductor material film 1332A. The retained portion of the conductive film 2431A can be divided into the conductive portion 324 and the conductive film 3331. The retained portion of the gate oxide layer 7224A can be divided into the insulating film 123 and the gate oxide layer 7224B. The hole 2601 can separate the semiconductor layer 1221 from the semiconductor material film 1332B. The hole 2601 can separate the semiconductor layer 1222 from the semiconductor material film 1332A. The hole 2601 can separate the conductive portion 324 from the conductive film 3331. The hole 2601 can separate the insulating film 123 from the gate oxide layer 7224B.

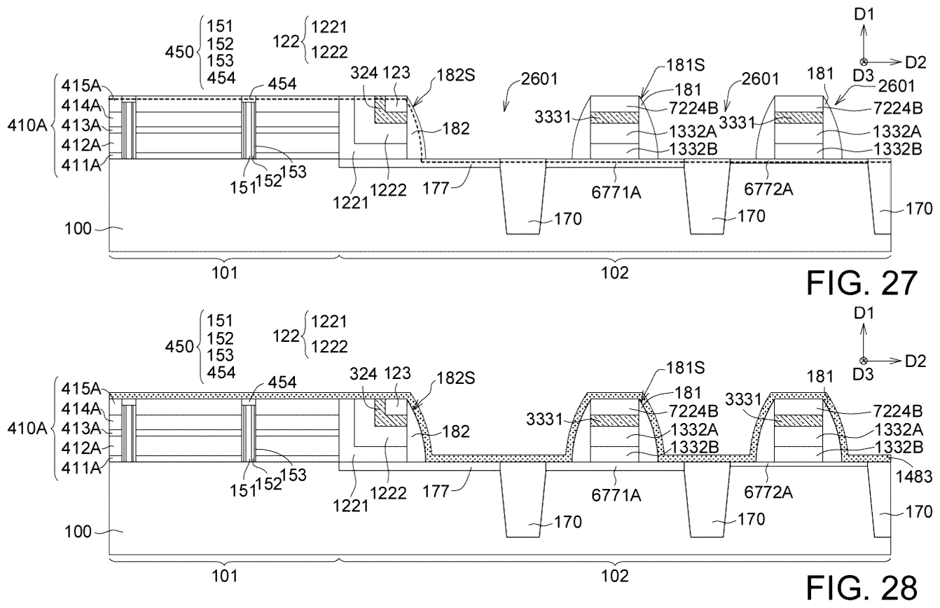

Referring to FIG. 27, FIG. 27 shows a schematic cross-sectional view of the structure at one stage of the method for manufacturing the memory device. Spacers 181 and at least one spacer 182 are formed in the peripheral region 102. The spacer 181 and the spacer 182 are in the holes 2601. FIG. 27 illustrates the spacer 181 and the spacer 182 as having arc-shaped sidewalls 181S and 182S respectively, but the present disclosure is not limited thereto. The spacer 181 may adjoin the sidewall of the semiconductor film 1332, the sidewall of the conductive film 3331 and the sidewall of the gate oxide layer 7224B. The spacer 182 may adjoin the sidewall of the extension portion 122, the sidewall of the conductive portion 324 and the sidewall of the insulating film 123. Insulating materials (i.e. the materials of the spacer 181 and the spacer 182) may be formed in the holes 2601 through a deposition process, and the insulating materials may fill the holes 2601. Then, a portion of the insulating materials may be removed through an etching process; the retained portion of the insulating materials can be divided into the spacer 181 and the spacer 182.

In an embodiment, after the spacer 181 and the spacer 182 are formed, an ion implantation process can be performed to the surface of the structure shown in FIG. 27 (such as the surface marked with a dotted line in FIG. 27) to introduce N-type or P-type dopants to the surface of the structure shown in FIG. 27. The ion implantation process can be performed simultaneously to the structure in the array region 101 and the structure in the peripheral region 102.

Referring to FIG. 28, FIG. 28 shows a schematic cross-sectional view of the structure at one stage of the method for manufacturing the memory device. A cover layer 1483 is formed. The cover layer 1483 may cover the upper surface of the layer stack 410A, the upper surface of the semiconductor layer 1221, the upper surface of the semiconductor layer 1222, the upper surface of the conductive portion 324, the upper surface of the insulating film 123, the sidewall 182S of the spacer 182, the upper surface of the dielectric film 177, the upper surfaces of the shallow trench isolations 170, the upper surface of the dielectric film 6771A, the sidewalls 181S of the spacers 181, the upper surfaces of the gate oxide layers 7224B, and the upper surface of dielectric film 6772A. The cover layer 1483 may be conformally formed on the layer stack 410A, the extension portion 122, the conductive portion 324, the insulating film 123, the spacer 182, the dielectric film 177, the shallow trench isolations 170, the dielectric film 6771A, the spacers 181, and the gate oxide layers 7224B through a deposition process.

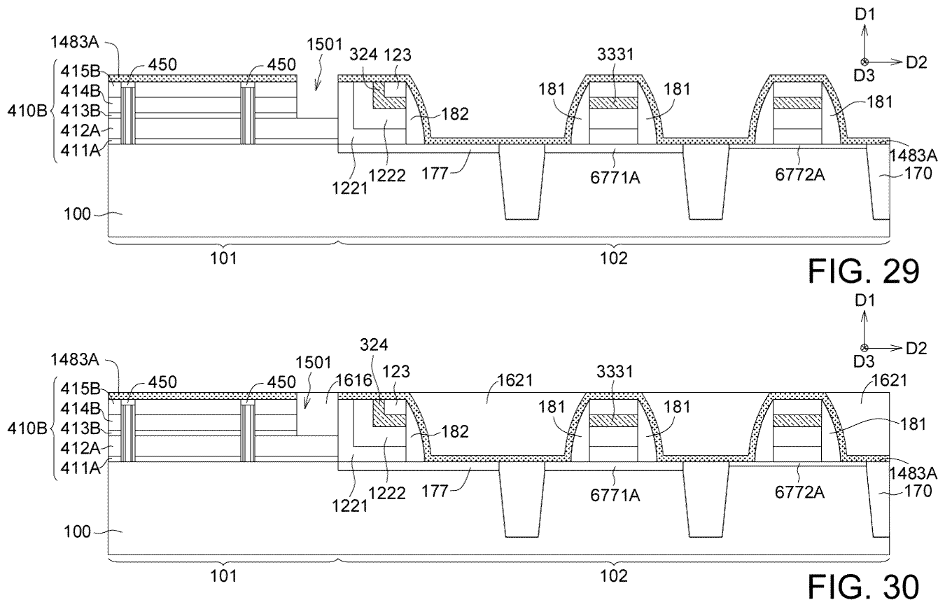

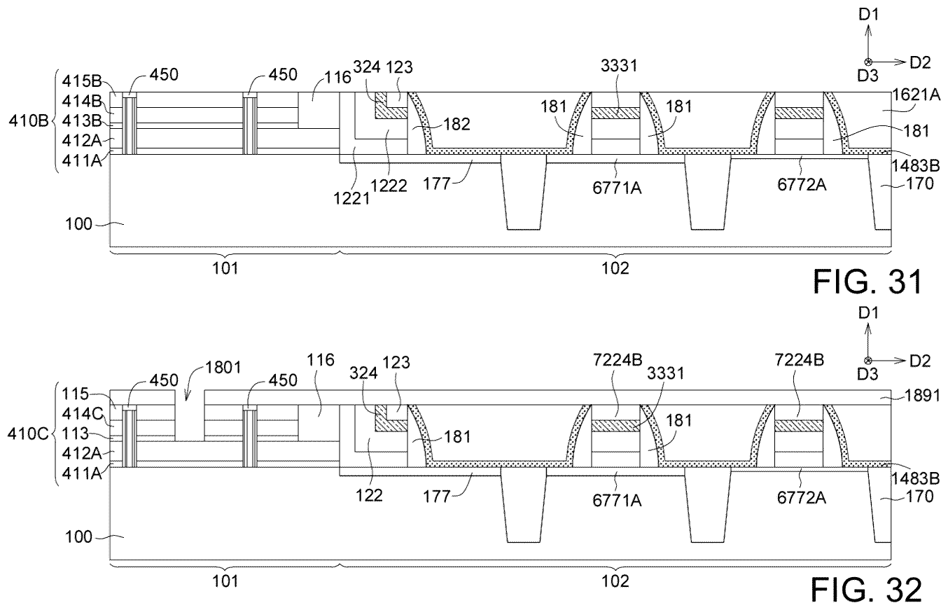

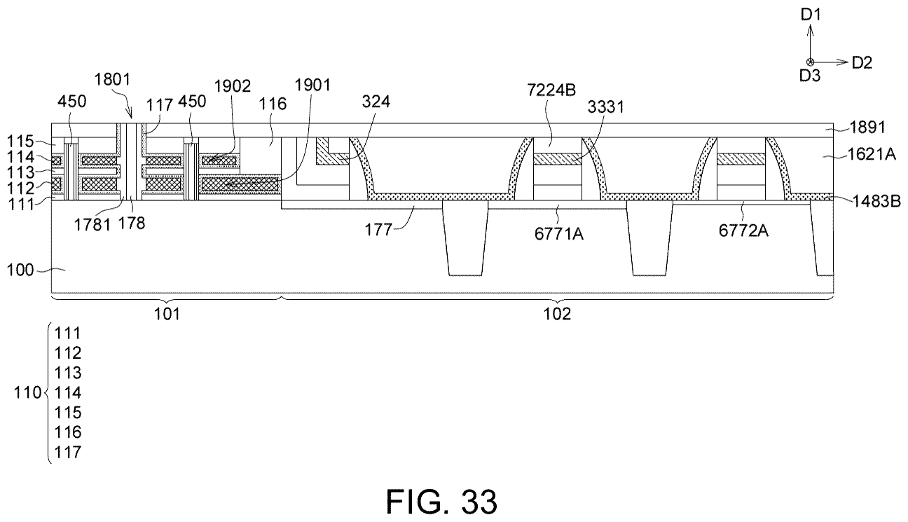

Referring to FIGS. 29 to 33, FIGS. 29 to 33 shows schematic cross-sectional views of the structures at stages of the method for manufacturing the memory device. Holes 1501 are formed in the array region 101 (FIG. 29). An insulating layer 1616 is formed in the array region 101; an insulating film 1621 is formed in the peripheral region 102 (FIG. 30). An insulating film 1621A, a cover layer 1483B and an insulating layer 116 are formed (FIG. 31). In other embodiments, the step shown in FIG. 31 can be omitted. An interlayer insulating layer 1891 and a hole 1801 penetrating the interlayer insulating layer 1891 are formed (FIG. 32). In the array region 101, a stacked structure 110 including an insulating layer 111, a conductive layer 112, an insulating layer 113, a conductive layer 114, an insulating layer 115, an insulating layer 116 and a barrier layer 117, a conductive pillar 178 penetrating the stacked structure 110, and an separation element 1781 disposed between the conductive pillar 178 and the barrier layer 117 are formed (FIG. 33).

In an embodiment, the structures shown in FIGS. 29 to 33 can be formed through the manufacturing method and materials described with reference to FIGS. 15 to 19, which will not be repeated here.

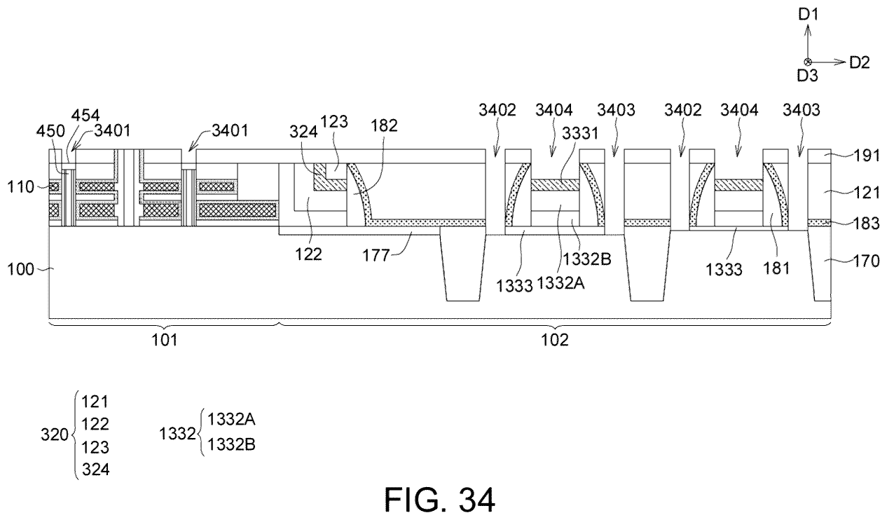

Referring to FIG. 34, FIG. 34 shows a schematic cross-sectional view of the structure at one stage of the method for manufacturing the memory device. An interlayer insulating layer 191 is formed. A portion of the interlayer insulating layer 191 is in the array region 101, and another portion of the interlayer insulating layer 191 is in the peripheral region 102. Holes 3401 penetrating the interlayer insulating layer 191 are formed in the array region 101. Holes 3402 and 3403 penetrating the interlayer insulating layer 191, the insulating film 121, and the cover layer 183 are formed in the peripheral region 102. Holes 3404 penetrating the interlayer insulating layer 191 and the insulating film 121 are formed in the peripheral region 102. The number and location of holes 3401 may correspond to the number and location of channel pillars 450. An upper surface of the channel pillar 450 (i.e. the upper surface of the pad 454) and a sidewall of the interlayer insulating layer 191 may be exposed by the hole 3401. The holes 3402 and 3403 may be disposed on opposite sides of the hole 3404. The number and location of the holes 3404 may correspond to the number and location of the semiconductor film 1332. The holes 3402 and 3403 may extend to the upper surface of the substrate 100 along the first direction D1. The holes 3402 and 3403 may expose the substrate 100. The hole 3404 may expose the conductive film 3331.

A portion of the interlayer insulating layer 1891 may be removed through an etching process to form the hole 3401. A portion of the interlayer insulating layer 1891, a portion of the insulating film 1621A, a portion of the cover layer 1483B, a portion of the dielectric film 6771A, and a portion of the dielectric film 6772A may be removed through an etching process to form the holes 3402 and 3403. A portion of the interlayer insulating layer 1891 and the gate oxide layer 7224B may be removed through an etching process to form the hole 3404. After performing the etching process to form the holes 3401 to 3404, the retained portion of the interlayer insulating layer 1891 is the interlayer insulating layer 191, the retained portion of the insulating film 1621A is the insulating film 121, the retained portion of the cover layer 1483B is the cover layer 183, and the retained portions of the dielectric film 6771A and the dielectric film 6772A are the dielectric films 1333. The insulating film 121, the extension portion 122, the insulating film 123 and the conductive portion 324 can form a stacked structure 320.

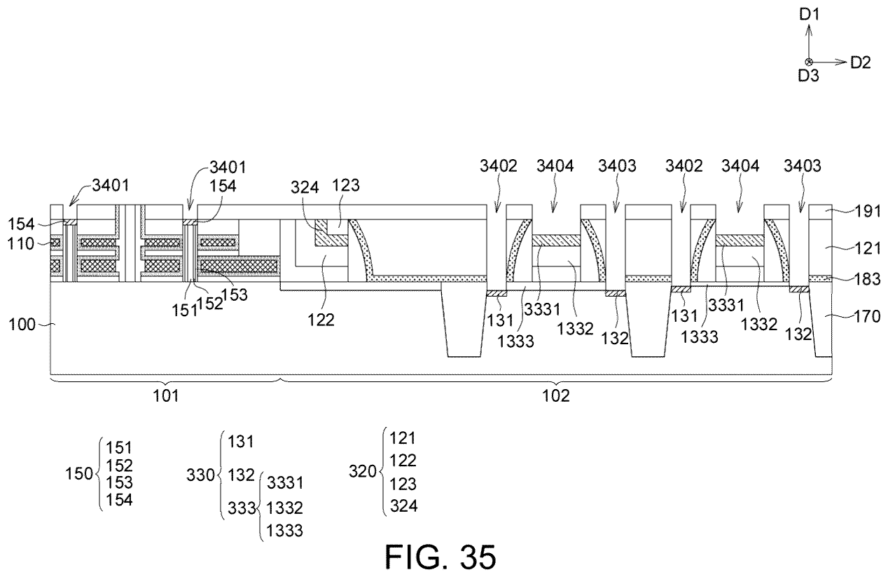

Referring to FIG. 35, FIG. 35 shows a schematic cross-sectional view of the structure at one stage of the method for manufacturing the memory device. At least one transistor 330 is formed in the peripheral region 102. A channel pillar 150 is formed in the array region 101. In an embodiment, a metal material may be formed in the holes 3401 to 3404 through a deposition process, and then a rapid thermal process (RTP) can be used to react the metal material (such as titanium, tungsten, cobalt or nickel) with the semiconductor material (such as silicon) below it to form the pad 154 in the hole 3401, the source 131 in the hole 3402, and the drain 132 in the hole 3403. In the present embodiment, the pad 454 reacts with the metal material and becomes the pad 154, a portion of the substrate 100 reacts with the metal material to form the source 131, and a portion of the substrate 100 reacts with the metal material to form the drain 132. In another embodiment, an ion implantation process can be performed to introduce N-type or P-type dopants to the surfaces exposed by the holes 3401 to 3403, thereby forming the pad 154 in the hole 3401, the source 131 in the hole 3402, and the drain 132 in the hole 3403. The conductive film 3331, the semiconductor film 1332 and the dielectric film 1333 can form the gate 133. The source 131, the drain 132 and the gate 333 can form the transistor 330. The insulating pillar 151, the channel layer 152, the charge storage layer 153 and the pad 154 can form the channel pillar 150. In an embodiment, after the pad 154 and the transistor 330 are formed, unreacted metal material may be removed by an etching process.

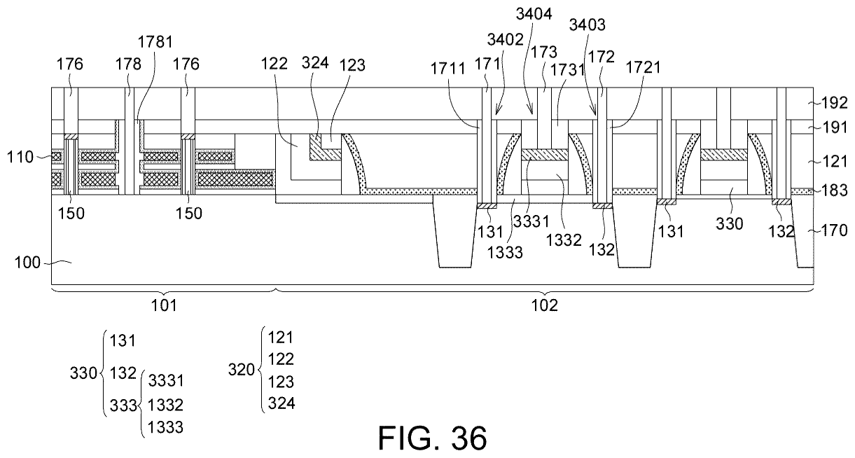

Referring to FIG. 36, FIG. 36 shows a schematic cross-sectional view of the structure at one stage of the method for manufacturing the memory device. An interlayer insulating layer 192 is formed. A portion of the interlayer insulating layer 192 is in the array region 101, and another portion of the interlayer insulating layer 192 is in the peripheral region 102. A channel contact structure 176 is formed in the array region 101. A source contact structure 171, a separation element 1711 on the sidewall of the source contact structure 171, a drain contact structure 172, a separation element 1721 on the sidewall of the drain contact structure 172, a gate contact structure 173, and a separation element 1731 on the sidewall of the gate contact structure 173 are formed in the peripheral region 102. The separation element 1711 may be formed in the hole 3402, the separation element 1721 may be formed in the hole 3403, and the separation element 1731 may be formed in the hole 3404 through a deposition process. Next, the interlayer insulating layer 192 may be formed above the interlayer insulating layer 191 through a deposition process. Then, the channel contact structure 176 penetrating the interlayer insulating layers 191 and 192, the source contact structure 171 penetrating the interlayer insulating layer 192 and the separation element 1711, the drain contact structure 172 penetrating the interlayer insulating layer 192 and the separation element 1721, and the gate contact structure 173 penetrating the interlayer insulating layer 192 and the separation element 1731 may be formed by an etching process and a deposition process.

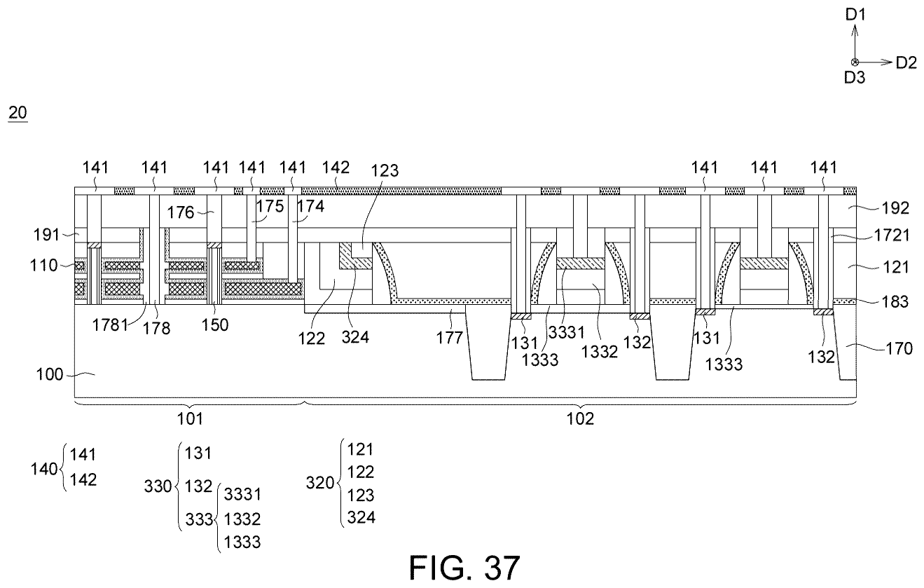

Referring to FIG. 37, FIG. 37 shows a schematic cross-sectional view of the structure at one stage of the method for manufacturing the memory device. A conductive contact structure 175 and a conductive contact structure 174 are formed. A metal routing layer 140 including an insulating material 142 and conductive lines 141 are formed on the interlayer insulating layer 192. The conductive contact structure 175 and the conductive contact structure 174 may be formed in the array region 101 through an etching process and a deposition process. After the conductive contact structure 175 and the conductive contact structure 174 are formed, the metal routing layer 140 may be formed in the array region 101 and the peripheral region 102 through an etching process and a deposition process. In an embodiment, the steps shown in FIGS. 36 and 37 can be performed in the back-end-of-the-line (BEOL) process of the semiconductor manufacturing process.

In an embodiment, through the method schematically illustrated in FIGS. 24 to 37, the memory device 20 as shown FIG. 3 is provided.

The conventional method for manufacturing a memory device with CMOS near array (CNA) architecture or CMOS under array (CUA) architecture is to form the peripheral circuit first and then form the memory array. However, the high-temperature processing steps used to form the memory array will adversely affect the peripheral circuit and reduce the performance of the peripheral circuit. The method for manufacturing the memory device according to the present disclosure alternates the manufacturing steps of the memory array with the manufacturing steps of the peripheral circuit, which can avoid or reduce the adverse effects of high-temperature processing steps on the peripheral circuit, improve the performance of the memory device, and provide a wider process window. The method for manufacturing the memory device according to the present disclosure performs the ion implantation process (for forming the gate of the transistor) after forming the channel layer and the charge storage layer, which can avoid or reduce the adverse effects on the state of the ion implantation area caused by high-temperature processing steps for forming the channel layer and the charge storage layer. Therefore, the present disclosure can avoid the thermal budget of the manufacturing process of memory array being limited by peripheral circuit can increase the thermal budget during memory array manufacturing, can increase the crystallinity of the channel layer (due to the increase in thermal budget), and can improve the carrier mobility of the memory device. In addition, in order to match the temperature of the high-temperature processing step for forming the memory array, the conventional method for manufacturing the memory device uses materials with high-temperature resistance (usually with higher resistance values) to form the transistor instead of materials that are not high-temperature resistant (usually with lower resistance values); the memory device and the method for manufacturing the same according to the present disclosure can use the materials with lower resistance (such as titanium silicide, tungsten silicide, cobalt silicide and nickel silicide) as the source and/or drain and/or gate of the transistor, which can improve contact resistance, gate resistance, performance of device and thermal budge.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory device, comprising:
a substrate comprising an array region and a peripheral region;
a first stacked structure in the array region, wherein the first stacked structure comprises a first conductive layer, a second conductive layer and an insulating layer between the first conductive layer and the second conductive layer, and the first conductive layer, the insulating layer and the second conductive layer are stacked along a first direction;
a second stacked structure in the peripheral region;
at least one transistor in the second stacked structure, wherein the at least one transistor comprises a conductive film, a dielectric film and a semiconductor film stacked along the first direction; and
a metal routing layer above the first stacked structure and the second stacked structure and electrically connected to the at least one transistor, the first conductive layer and the second conductive layer.

2. The memory device according to claim 1, further comprising at least one channel pillar and a plurality of memory cells, wherein the at least one channel pillar extends along a second direction opposite to the first direction and penetrates the first stacked structure, the first conductive layer is closer to the substrate than the second conductive layer, and the plurality of memory cells are between the second conductive layer and the at least one channel pillar.

3. The memory device according to claim 2, further comprising a source contact structure and a drain contact structure, wherein the at least one transistor comprises a source, a drain and a gate, the gate is formed by the conductive film, the dielectric film and the semiconductor film, the source and the drain are in the substrate, the source contact structure and the drain contact structure extend along the second direction to a surface of the substrate, a height of the source contact structure from the substrate and a height of the drain contact structure from the substrate are greater than a height of the at least one channel pillar from the substrate.

4. The memory device according to claim 2, further comprising a conductive pillar penetrating the first stacked structure, extending along the second direction to a surface of the substrate, and electrically connected to the substrate.

5. The memory device according to claim 4, further comprising a source contact structure and a drain contact structure, wherein the at least one transistor comprises a source, a drain and a gate, the gate is formed by the conductive film, the dielectric film and the semiconductor film, the source and the drain are in the substrate, a height of the source contact structure from the substrate and a height of the drain contact structure from the substrate are greater than a height of the conductive pillar from the substrate.

6. The memory device according to claim 1, further comprising a first conductive contact structure and a second conductive contact structure, wherein the first conductive contact structure is above the first conductive layer and electrically connected to the first conductive layer, the second conductive contact structure is above the second conductive layer and electrically connected to the second conductive layer, the first conductive contact structure and the second contact structure are electrically connected to the metal routing layer.

7. The memory device according to claim 1, wherein the second stacked structure comprises an extension portion adjoining an end of the first conductive layer, wherein the extension portion comprises semiconductor layers extending and stacked along the first direction and a direction perpendicular to the first direction.

8. The memory device according to claim 7, further comprising at least one first spacer in the second stacked structure and on sidewalls of the conductive film and the semiconductor film of the at least one transistor.

9. The memory device according to claim 8, further comprising a second spacer in the second stacked structure and at an end of the extension portion away from the first conductive layer.

10. The memory device according to claim 9, wherein a height of the at least one first spacer and a height of the second spacer are substantially the same.

11. The memory device according to claim 1, further comprising a plurality of shallow trench isolations (STI) disposed in the peripheral region and below the second stacked structure, wherein the plurality of shallow trench isolations and the at least one transistor are disposed alternately.

12. The memory device according to claim 11, further comprising a cover layer covering the plurality of shallow trench isolations.

13. The memory device according to claim 1, further comprising a spacer in the second stacked structure, wherein the at least one transistor comprises a source, a drain and a gate, the gate is formed by the conductive film, the dielectric film and the semiconductor film, the source and the drain are in the substrate, and the spacer is on a sidewall of the gate.

14. The memory device according to claim 13, wherein in the first direction, an end of the spacer is higher than an upper surface of the conductive film.

15. The memory device according to claim 13, wherein the spacer is above the dielectric film and between the source and the semiconductor film.

16. The memory device according to claim 4, wherein the conductive film comprises tungsten silicide.

17. A method for manufacturing a memory device, comprising:
providing a substrate comprising an array region and a peripheral region;
forming a layer stack in the array region, wherein the layer stack comprises a semiconductor material layer, a dielectric layer and an insulating layer between the semiconductor material layer and the dielectric layer;
forming a channel pillar penetrating the layer stack;
forming an extension portion adjoining the layer stack, wherein the extension portion comprises semiconductor layers extending and stacked along a first direction and a second direction perpendicular to the first direction; and
forming at least one transistor in the peripheral region, wherein the at least one transistor comprises a conductive film, a dielectric film and a semiconductor film stacked on top of one another.

18. The method according to claim 17, further comprising:
forming a spacer in the peripheral region, wherein the spacer is on a sidewall of the semiconductor film.

19. The method according to claim 18, further comprising:
forming a cover layer in the peripheral region, wherein the cover layer covers the spacer.

20. The method according to claim 18, further comprising:
forming another spacer in the peripheral region, wherein the another spacer is on a sidewall of the extension portion.
